(19) United States
(12) Patent Application Publication
(10) Pub. No.: US 2025/0286512 A1
(43) Pub. Date: Sep. 11, 2025

(54) TRACKER MODULE

(71) Applicant: Murata Manufacturing Co., Ltd., Nagaokakyo-shi (JP)

(72) Inventors: John R. HOVERSTEN, Waltham, MA (US); Yevgeniy A. TKACHENKO, Waltham, MA (US); Scott BAKER, Waltham, MA (US); Kouji YAMAGUCHI, Nagaokakyo-shi (JP); Kenzou OOMORI, Nagaokakyo-shi (JP)

(21) Appl. No.: 19/215,989

(22) Filed: May 22, 2025

Related U.S. Application Data
(63) Continuation of application No. PCT/JP2023/042240, filed on Nov. 24, 2023.
(60) Provisional application No. 63/431,060, filed on Dec. 8, 2022.

(51) Int. Cl. H03F 1/02; H03F 3/00; H03F 3/24

(52) U.S. Cl. CPC H03F 1/0227; H03F 3/005; H03F 3/245; H03F 2200/102; H03F 2200/105; H03F 2200/451

(57) ABSTRACT

A tracker module is provided that includes a module laminate, and an integrated circuit disposed at the module laminate. The integrated circuit includes at least one switch included in a pre-regulator circuit; at least one switch included in a switched-capacitor circuit; at least one switch included in an output switching circuit; and a digital control circuit. In plan view of the module laminate, at least one of the at least one switch included in the output switching circuit; or the digital control circuit is disposed between the at least one switch included in the pre-regulator circuit and the at least one switch included in the switched-capacitor circuit.

### CROSS REFERENCE TO RELATED APPLICATIONS

This application is a continuation of International Application No. PCT/JP2023/042240, filed Nov. 24, 2023, which claims priority to U.S. Provisional Patent Application No. 63/431,060, filed Dec. 8, 2022, the entire contents of each of which are hereby incorporated by reference.

### TECHNICAL FIELD

The exemplary aspects of the present disclosure relate to a tracker module.

### BACKGROUND

In general, U.S. Pat. No. 9,755,672 discloses a supply modulator (e.g., a tracker circuit) configured to, based on an envelope signal, supply a power supply voltage to a power amplifier circuit. The supply modulator includes a magnetic converter circuit (magnetic regulation stage: pre-regulator circuit) configured to convert a voltage, a switched-capacitor circuit (switched-capacitor voltage balancer stage) configured to generate, from the voltage, a plurality of voltages having different voltage levels, and an output switching circuit (output switching stage) configured to select and output at least one of the plurality of voltages. The magnetic converter circuit includes switches and a power inductor. The switched-capacitor circuit includes switches and capacitors. Moreover, the output switching circuit includes switches.

With the configuration of the tracker circuit disclosed in U.S. Pat. No. 9,755,672, the switched-capacitor circuit generates a plurality of discrete voltages based on a voltage output from the pre-regulator circuit. As a result, the configuration may lead to efficiency degradation of the tracker circuit due to heat generation.

### SUMMARY OF THE INVENTION

In view of the foregoing, the exemplary aspects of the present disclosure provide a tracker module that reduces efficiency degradation caused by heat generation.

According to an exemplary aspect, a tracker module is provided that includes a module laminate, and a single integrated circuit disposed at the module laminate. The integrated circuit includes at least one switch included in a converter circuit that is configured to convert an input voltage into a first voltage; at least one switch included in a switched-capacitor circuit that is configured to generate a plurality of discrete second voltages based on the first voltage; at least one switch included in an output switching circuit that is configured to selectively output at least one of the plurality of discrete second voltages generated by the switched-capacitor circuit; and a digital control circuit configured to, based on a digital control signal corresponding to an envelope signal, cause the output switching circuit to selectively output at least one of the plurality of discrete second voltages. In plan view of the module laminate, at least one of: (i) the at least one switch included in the output switching circuit; or (ii) the digital control circuit is disposed between the at least one switch included in the converter circuit and the at least one switch included in the switched-capacitor circuit.

In another exemplary aspect, a tracker module is provided that includes a module laminate, a first integrated circuit, a second integrated circuit, a third integrated circuit, and a digital control circuit. The first integrated circuit is disposed at the module laminate, and includes at least one switch included in a converter circuit, which is configured to convert an input voltage into a first voltage. The second integrated circuit is disposed at the module laminate, and includes at least one switch included in a switched-capacitor circuit, which is configured to generate a plurality of discrete second voltages based on the first voltage. The third integrated circuit is disposed at the module laminate, and includes at least one switch included in an output switching circuit, which is configured to selectively output at least one of the plurality of discrete second voltages generated by the switched-capacitor circuit. The digital control circuit is configured to, based on a digital control signal corresponding to an envelope signal, cause the output switching circuit to selectively output at least one of the plurality of discrete second voltages. In a plan view of the module laminate, at least one of: (i) the at least one switch included in the output switching circuit; or (ii) the digital control circuit is disposed between the at least one switch included in the converter circuit and the at least one switch included in the switched-capacitor circuit.

In another exemplary aspect, a tracker module is provided that includes a module laminate, and a single integrated circuit disposed at the module laminate. The integrated circuit includes a first switch, a second switch, a third switch, a fourth switch, a fifth switch, a sixth switch, a seventh switch, and an eighth switch that are included in a switched-capacitor circuit; a ninth switch and a tenth switch that are included in an output switching circuit connected to the switched-capacitor circuit; an eleventh switch and a twelfth switch that are included in a converter circuit connected to the switched-capacitor circuit; and a digital control circuit configured to control the first to twelfth switches. The switched-capacitor circuit includes a first capacitor having a first electrode and a second electrode; a second capacitor having a third electrode and a fourth electrode; and the first to eighth switches. A first terminal of the first switch and a first terminal of the third switch are connected to the first electrode. A first terminal of the second switch and a first terminal of the fourth switch are connected to the second electrode. A first terminal of the fifth switch and a first terminal of the seventh switch are connected to the third electrode. A first terminal of the sixth switch and a first terminal of the eighth switch are connected to the fourth electrode. A second terminal of the first switch, a second terminal of the second switch, a second terminal of the fifth switch, and a second terminal of the sixth switch are connected to each other. A second terminal of the third switch is connected to a second terminal of the seventh switch. A second terminal of the fourth switch is connected to a second terminal of the eighth switch. The output switching circuit includes: a first output terminal; the ninth switch connected between the first output terminal, and the second terminal of the first switch, the second terminal of the second switch, the second terminal of the fifth switch, and the second terminal of the sixth switch; and the tenth switch connected between the first output terminal, and the second terminal of the third switch and the second terminal of the seventh switch. The converter circuit includes: an input terminal; the eleventh switch connected between the input terminal and a first end of a power inductor; and the twelfth switch connected between the first end of the power inductor and ground. A second end of the power inductor is connected to the second terminal of the first switch, the second terminal of the second switch, the second terminal of the fifth switch, and the second terminal of the sixth switch. In a plan view of the module laminate, at least one of: (i) the ninth switch and the tenth switch, and (ii) the digital control circuit is disposed between: the eleventh switch and the twelfth switch; and the first switch, the second switch, the third switch, the fourth switch, the fifth switch, the sixth switch, the seventh switch, and the eighth switch.

The exemplary aspects of the present disclosure provide a tracker module that reduces efficiency degradation caused by heat generation.

### BRIEF DESCRIPTION OF DRAWINGS

FIG. 1A is a graph illustrating an example of the progression of power supply voltage in an average power tracking (APT) mode.

FIG. 1B is a graph illustrating an example of the progression of power supply voltage in an analog ET mode.

FIG. 1C is a graph illustrating an example of the progression of power supply voltage in a digital ET mode.

FIG. 2 is a circuit diagram of a tracker circuit and a communication device according to exemplary embodiments.

FIG. 3 is a circuit diagram of a pre-regulator circuit, a switched-capacitor circuit, an output switching circuit, and a filter circuit according to the exemplary embodiments.

FIG. 4 is a circuit diagram of a digital control circuit according to the exemplary embodiments.

FIG. 5A is a plan view of a tracker module according to an example.

FIG. 5B is a plan view of the tracker module according to an example.

FIG. 5C is a cross-sectional view of the tracker module according to an example.

FIG. 5D is a plan view of a portion of an integrated circuit according to an example.

FIG. 6A is a plan view of a tracker module according to Modification 1.

FIG. 6B is a cross-sectional view of the tracker module according to 1.

FIG. 7 is a plan view of a tracker module according to Modification 2.

FIG. 8 is a plan view of a tracker module according to Modification 3.

FIG. 9A is a plan view of a tracker module according to Modification 4.

FIG. 9B is a cross-sectional view of the tracker module according to Modification 4.

FIG. 10 is a plan view of a tracker module according to Modification 5.

FIG. 11A is a plan view of a tracker module according to Modification 6.

FIG. 11B is a plan view of the tracker module according to Modification6.

FIG. 11C is a cross-sectional view of the tracker module according to Modification 6.

### DETAILED DESCRIPTION OF EMBODIMENTS

Exemplary embodiments of the present disclosure will now be described in detail below with reference to the drawings. The embodiments described below each represent generic or specific examples. Features presented in the following embodiments, such as numerical values, shapes, materials, constituent elements, and the positioning and connection of constituent elements, are illustrative only and not intended to be limiting of the exemplary aspects of the present disclosure.

The drawings are schematic in nature with emphases, omissions, or proportion adjustments made as necessary to illustrate the exemplary aspects of the present disclosure, and do not necessarily represent exact details. Accordingly, the illustrated shapes, positional relationships, and proportions may differ from the actuality. Throughout the drawings, identical reference signs are used to designate substantially identical features, and repetitive description will be sometimes omitted or simplified.

In the figures described below, the x-axis and the y-axis are orthogonal to each other in a plane parallel to a major face of a module laminate. Specifically, when the module laminate has a rectangular shape in plan view, the x-axis is parallel to a first side of the module laminate, and the y-axis is parallel to a second side orthogonal to the first side of the module laminate. A z-axis is an axis perpendicular to the major face of the module laminate. The z-axis has a positive direction defined as an upward direction, and a negative direction defined as a downward direction.

As used in the following description of circuit configurations according to the present disclosure, expressions such as “connected” can indicate not only that circuit elements are directly connected by a connection terminal and/or a wiring conductor, but also that circuit elements are electrically connected with another circuit element interposed therebetween. Expressions such as “connected between A and B” can refer to being positioned between A and B and connected to both A and B.

As used herein with regard to the positioning of components according to the exemplary aspects of the present disclosure, expressions such as “a component is disposed at a substrate” include that the component is disposed on a major face of the substrate, and that the component is disposed in the substrate. Expressions such as “a component is disposed on a major face of a substrate” include not only that the component is disposed in contact with the major face of the substrate, but also that the component is disposed above the major face without making contact with the major face (e.g., the component is stacked on another component disposed in contact with the major face). The expressions such as “a component is disposed on a major face of a substrate” may also include that the component is disposed at a recess defined in the major face. Expressions such as “a component is disposed in a substrate” include, in addition to the meaning that the component is encapsulated in the module laminate, the following meanings: the entirety of the component is disposed between opposite major faces of the substrate but part of the component is not covered by the substrate; and only part of the component is disposed in the substrate.

As used herein with regard to the positioning of components according to the exemplary aspects of the present disclosure, expressions such as “plan view of a module laminate” can indicate that an object or component is orthogonally projected onto an xy-plane and seen from the positive side of the z-axis. Expressions such as “A overlaps B in plan view” can indicate that at least part of the region of A orthogonally projected onto the xy-plane overlaps at least part of the region of B orthogonally projected onto the xy-plane. Expressions such as “A is disposed between B and C” can indicate that at least one of a plurality of line segments each connecting a given point in B and a given point in C passes through A.

As used herein with regard to the positioning of components according to the exemplary aspects of the present disclosure, expressions such as “A is disposed adjacent to B” indicate that A and B are disposed in proximity to each other. Specifically, such expressions can indicate that no other circuit component exists in a space where A faces B. In other words, the expressions such as “A is disposed adjacent to B” can indicate that none of a plurality of line segments each extending from a given point on a surface of A facing B to B in the direction normal to the surface passes through a circuit component other than A and B. In this regard, a circuit component can refer to a component including an active element and/or a passive element. That is, examples of such circuit components include active components such as transistors or diodes, and passive components such as inductors, transformers, capacitors, or resistors, but do not include electromechanical components such as terminals, connectors, or wiring.

As used in the exemplary aspects of the present disclosure, expressions such as “terminal” can refer to a point where a conductor within an element terminates. When the impedance of a conductor located between elements is sufficiently low, a terminal is interpreted not only as a single point, but also as any given point on the conductor located between the elements or as the entire conductor.

Further, “parallel”, “perpendicular”, or other such expressions indicative of the relationship between elements, and “rectangular” or other such expressions indicative of a shape of an element, as well as numerical ranges are not intended to represent only their strict meanings but are meant to also include their substantial equivalents, for example, equivalents with deviations or differences of about several percent.

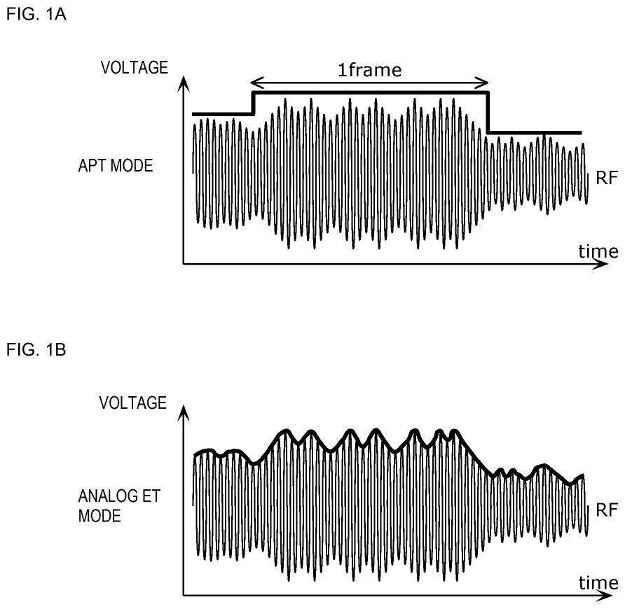

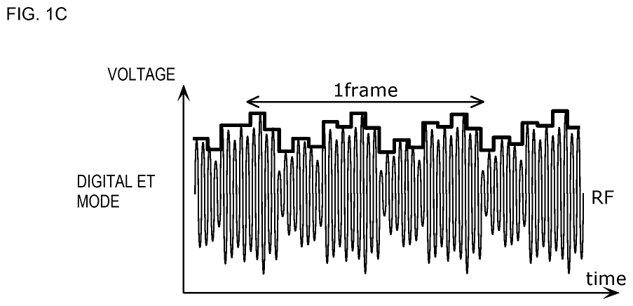

First, as a technique for efficiently amplifying a radio frequency signal, a tracking mode is described below in which a power amplifier receives a power supply voltage that is dynamically adjusted with the passage of time based on the radio frequency signal. A tracking mode refers to a mode that dynamically adjusts the power supply voltage to be applied to a power amplifier. Several types of tracking modes exist, of which an average power tracking (APT) mode and an envelope tracking (ET) mode (including an analog ET mode and a digital ET mode) will now be described with reference to FIGS. 1A to 1C. In FIGS. 1A to 1C, the horizontal axis represents time, and the vertical axis represents voltage. A thick solid line represents power supply voltage, and a thin solid line (waveform) represents modulated signal.

FIG. 1A is a graph illustrating an example of the progression of power supply voltage in the APT mode. In the APT mode, the power supply voltage is varied across a plurality of discrete voltage levels in units of one frame based on average power. As a result, a power supply voltage signal forms a rectangular wave.

According to an exemplary aspect, a frame can refer to a unit forming a radio frequency signal (e.g., a modulated signal). For example, in 5th Generation New Radio (5G NR) and Long Term Evolution (LTE), a frame includes ten subframes. Each subframe includes a plurality of slots. Each slot includes a plurality of symbols. A subframe has a length of 1 ms, and a frame has a length of 10 ms according to an exemplary aspect.

According to an exemplary aspect, a mode in which the voltage level is varied in units of one frame or in larger units based on average power is referred to as an APT mode, which is distinguished from a mode in which the voltage level is varied in units smaller than one frame (e.g., in units of subframes, slots, or symbols). For example, a mode in which the voltage level is varied in units of symbols is referred to as a symbol power tracking (SPT) mode, which is distinguished from the APT mode.

FIG. 1B is a graph illustrating an example of the progression of power supply voltage in the analog ET mode. In the analog ET mode, the power supply voltage is varied continuously based on an envelope signal to thereby track the envelope of a modulated signal.

An envelope signal is a signal representing the envelope of a modulated signal. An envelope value is expressed as, for example, the square root of (I²+Q²). In this case, (I, Q) represents a constellation point. A constellation point is a point representing, on a constellation diagram, a signal modulated by digital modulation. (I, Q) is determined by, for example, a baseband integrated circuit (BBIC) based on, for example, transmission information.

FIG. 1C is a graph illustrating an example of the progression of power supply voltage in the digital ET mode. In the digital ET mode, the power supply voltage is varied across a plurality of discrete voltage levels within one frame based on an envelope signal to thereby track the envelope of a modulated signal. As a result, the power supply voltage signal forms a rectangular wave.

### Exemplary Embodiments

A communication device 6 according to the embodiments corresponds to user equipment (UE) in a cellular network. Typical examples of the communication device 6 include a mobile phone, a smartphone, a tablet computer, and a wearable device. The communication device 6 may be an Internet of Things (IoT) sensor device, a medical/healthcare device, a vehicle, an unmanned aerial vehicle (UAV) (a so-called drone), or an automated guided vehicle (AGV). The communication device 6 can be configured as a base station (BS) in a cellular network according to an exemplary aspect.

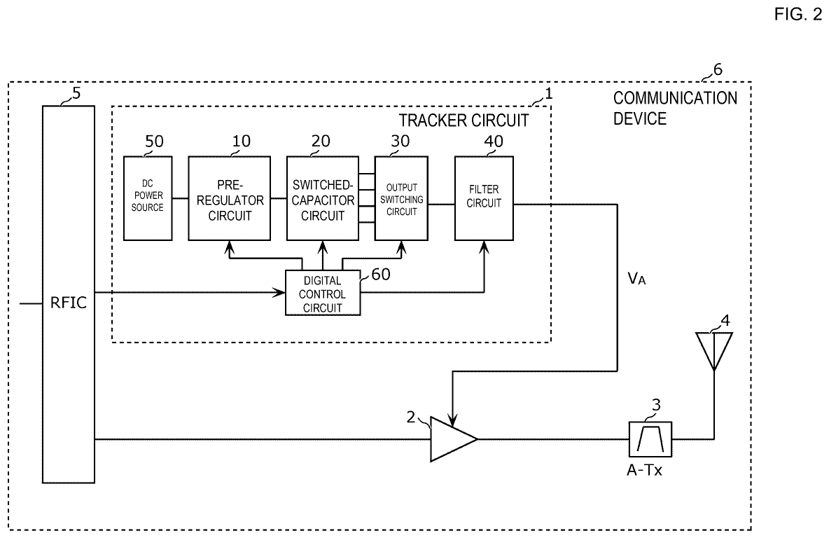

The circuit configuration of each of the communication device 6 and a tracker circuit 1 according to the embodiments will now be described with reference to FIG. 2. FIG. 2 is a circuit diagram of the tracker circuit 1 and the communication device 6 according to the embodiments.

FIG. 2 illustrates an exemplary circuit configuration. The communication device 6 and the tracker circuit 1 may be implemented by using any one of a wide variety of circuit implementations and circuit technologies. Therefore, the description of the communication device 6 and the tracker circuit 1 provided below is not to be construed restrictively.

### 1 Circuit Configuration of Communication Device 6

First, the communication device 6 according to the embodiments will be described with reference to FIG. 2. The communication device 6 includes the tracker circuit 1, a power amplifier 2, a filter 3, a radio frequency integrated circuit (RFIC) 5, and an antenna 4.

According to an exemplary aspect, the tracker circuit 1 is configured to, based on a tracking mode, supply a plurality of discrete voltages VA to the power amplifier 2. The tracking mode used may be, but is not limited to, the digital ET mode or the SPT mode. As illustrated in FIG. 2, the tracker circuit 1 includes a pre-regulator circuit 10, a switched-capacitor circuit 20, an output switching circuit 30, a filter circuit 40, a direct current (DC) power source 50, and a digital control circuit 60.

The pre-regulator circuit 10 is an example of a converter circuit, and includes a power inductor and a switch. A power inductor is an inductor used to step up and/or step down a DC voltage. The power inductor is connected in series with a DC path. The power inductor may be connected (disposed in parallel) between the DC path and ground. The pre-regulator circuit 10 is configured to convert an input voltage into a first voltage by using the power inductor. According to an exemplary aspect, the pre-regulator circuit 10 may also be referred to as a magnetic regulator or a DC-DC converter.

The switched-capacitor circuit 20 includes a plurality of capacitors, and a plurality of switches. The switched-capacitor circuit 20 is configured to receive the first voltage from the pre-regulator circuit 10 and, from the first voltage, generate, as a plurality of discrete voltages, a plurality of second voltages each having a corresponding one of a plurality of discrete voltage levels. According to an exemplary aspect, the switched-capacitor circuit 20 may also be referred to as a switched-capacitor voltage balancer.

The output switching circuit 30 is configured to selectively output, to the power amplifier 2, at least one of the plurality of second voltages generated by the switched-capacitor circuit 20. The output switching circuit 30 is controlled based on a digital control signal.

The filter circuit 40 is configured to attenuate noise from the plurality of discrete voltages to be supplied to the power amplifier 2. According to an exemplary aspect, the filter circuit 40 may also be referred to as a pulse shaping filter or a transition shaping filter.

According to an exemplary aspect, the DC power source 50 is configured to supply a DC voltage to the pre-regulator circuit 10. A suitable, non-limiting example of the DC power source 50 is a rechargeable battery.

The digital control circuit 60 is configured to control the following components based on a digital control signal provided from the RFIC 5: the pre-regulator circuit 10, the switched-capacitor circuit 20, the output switching circuit 30, and the filter circuit 40. More specifically, the digital control circuit 60 is configured to, based on a digital control signal corresponding to an envelope signal, control the output switching circuit 30 to selectively output at least one of the plurality of discrete second voltages.

The tracker circuit 1 may be configured not to include at least one of the filter circuit 40 or the DC power source 50. In one example, the tracker circuit 1 may be configured not to include the DC power source 50. In another example, any combination of the pre-regulator circuit 10, the switched-capacitor circuit 20, the output switching circuit 30, and the filter circuit 40 may be integrated into a single circuit. In another example, the tracker circuit 1 may include a plurality of voltage supply circuits, instead of the pre-regulator circuit 10 and the switched-capacitor circuit 20. In this case, the output switching circuit 30 may be configured to select at least one of the plurality of voltage supply circuits.

The power amplifier 2 is connected between the RFIC 5 and the filter 3. Further, the power amplifier 2 is connected to the tracker circuit 1. The power amplifier 2 is configured to amplify, by using the plurality of discrete voltages VA received from the tracker circuit 1, a radio frequency signal RFA of Band A received from the RFIC 5.

The filter 3 is connected between the power amplifier 2 and the antenna 4. The filter 3 is a band pass filter with a passband that includes Band A.

Band A is a frequency band for communication systems built by using radio access technology (RAT). Band A is predefined by standardizing bodies or other entities (e.g., 3rd Generation Partnership Project (3GPP)® and Institute of Electrical and Electronics Engineers (IEEE)). Examples of such communication systems include 5th Generation New Radio (5G NR) systems, Long Term Evolution (LTE) systems, and Wireless Local Area Network (WLAN) systems.

The RFIC 5 is an example of a signal processing circuit that processes a radio frequency signal. Specifically, the RFIC 5 performs signal processing such as up-conversion on an input transmission signal to thereby generate a radio frequency transmission signal, and supplies the radio frequency transmission signal to the power amplifier 2. The RFIC 5 includes a control unit that controls the tracker circuit 1. The function of the RFIC 5 as a control unit may in part or in whole be implemented outside the RFIC 5 in an exemplary aspect.

The antenna 4 outputs a transmission signal of Band A received from the power amplifier 2 via the filter 3. The antenna 4 need not necessarily be included in the communication device 6.

The circuit configuration of the communication device 6 in FIG. 2 is illustrative and not intended to be limiting. For example, the communication device 6 may include a baseband signal processing circuit that performs signal processing by using an intermediate frequency band lower in frequency than the radio frequency signal RFA.

### 2 Circuit Configuration of Tracker Circuit 1

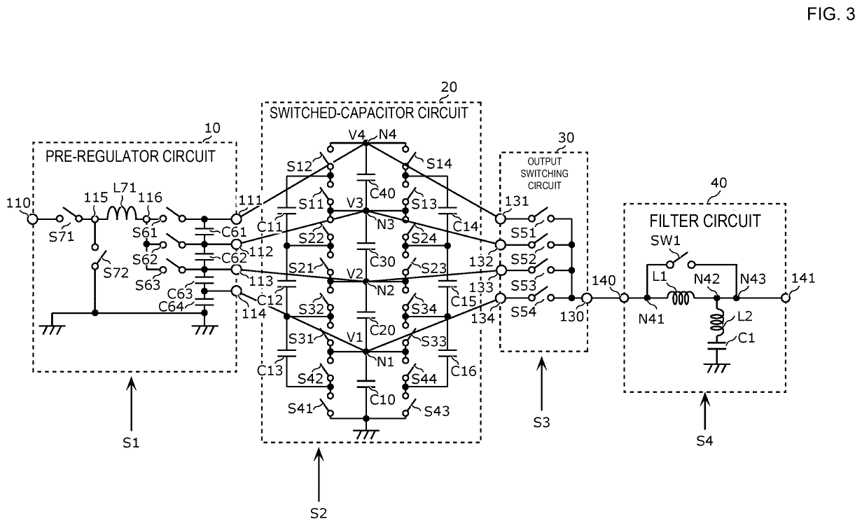

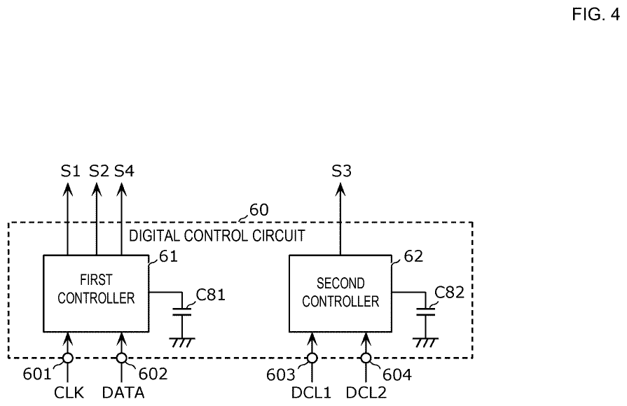

Now, with reference to FIGS. 3 and 4, the circuit configuration of each of the following components included in the tracker circuit 1 will be described: the pre-regulator circuit 10, the switched-capacitor circuit 20, the output switching circuit 30, the filter circuit 40, and the digital control circuit 60. FIG. 3 is a circuit diagram of the following components according to the embodiments: the pre-regulator circuit 10, the switched-capacitor circuit 20, the output switching circuit 30, and the filter circuit 40. FIG. 4 is a circuit diagram of the digital control circuit 60 according to the embodiments.

FIGS. 3 and 4 illustrate exemplary circuit configurations. The pre-regulator circuit 10, the switched-capacitor circuit 20, the output switching circuit 30, the filter circuit 40, and the digital control circuit 60 may be implemented by using any one of a wide variety of circuit implementations and circuit technologies. Therefore, the description of each circuit provided below is not to be construed restrictively.

### 2.1 Circuit Configuration of Switched-Capacitor Circuit 20

First, the circuit configuration of the switched-capacitor circuit 20 is described with reference to FIG. 3. As illustrated in FIG. 3, the switched-capacitor circuit 20 includes capacitors C11 to C16, capacitors C10, C20, C30 and C40, and switches S11 to S14, S21 to S24, S31 to S34, and S41 to S44. Energy and charge are input, at nodes N1 to N4, from the pre-regulator circuit 10 to the switched-capacitor circuit 20, and drawn, at the nodes N1 to N4, from the switched-capacitor circuit 20 to the output switching circuit 30.

Each of the capacitors C11 to C16 can be configured to function as a flying capacitor (sometimes also referred to as a transfer capacitor) in an exemplary aspect. That is, each of the capacitors C11 to C16 is used to step up or step down the first voltage supplied from the pre-regulator circuit 10. More specifically, the capacitors C11 to C16 transfer charge between the capacitors C11 to C16 and the nodes N1 to N4 so that voltages V1 to V4 (relative to the ground potential) that satisfy V1:V2:V3:V4=1:2:3:4 are maintained at the four nodes N1 to N4. The voltages V1 to V4 correspond to the plurality of second voltages each having a corresponding one of a plurality of discrete voltage levels.

The capacitor C11 is an example of a first capacitor, and has two electrodes. One of the two electrodes of the capacitor C11 is an example of a first electrode, and is connected to one terminal of the switch S11 and one terminal of the switch S12. The other of the two electrodes of the capacitor C11 is an example of a second electrode, and is connected to one terminal of the switch S21 and one terminal of the switch S22. For purposes of the exemplary aspects of the present disclosure, the term “one terminal” can be considered or referred to as a first terminal.

The capacitor C12 has two electrodes. One of the two electrodes of the capacitor C12 is connected to the one terminal of the switch S21 and the one terminal of the switch S22. The other of the two electrodes of the capacitor C12 is connected to one terminal of the switch S31 and one terminal of the switch S32.

The capacitor C13 has two electrodes. One of the two electrodes of the capacitor C13 is connected to the one terminal of the switch S31 and the one terminal of the switch S32. The other of the two electrodes of the capacitor C13 is connected to one terminal of the switch S41 and one terminal of the switch S42.

The capacitor C14 is an example of a second capacitor, and has two electrodes. One of the two electrodes of the capacitor C14 is an example of a third electrode, and is connected to one terminal of the switch S13 and one terminal of the switch S14. The other of the two electrodes of the capacitor C14 is an example of a fourth electrode, and is connected to one terminal of the switch S23 and one terminal of the switch S24.

The capacitor C15 has two electrodes. One of the two electrodes of the capacitor C15 is connected to the one terminal of the switch S23 and the one terminal of the switch S24. The other of the two electrodes of the capacitor C15 is connected to one terminal of the switch S33 and one terminal of the switch S34.

The capacitor C16 has two electrodes. One of the two electrodes of the capacitor C16 is connected to the one terminal of the switch S33 and the one terminal of the switch S34. The other of the two electrodes of the capacitor C16 is connected to one terminal of the switch S43 and one terminal of the switch S44.

A set of the capacitors C11 and C14, a set of the capacitors C12 and C15, and a set of the capacitors C13 and C16 are each configured to be charged and discharged in a complementary manner as a first phase and a second phase are repeated.

Specifically, in the first phase, the switches S12, S13, S22, S23, S32, S33, S42, and S43 are turned ON. As a result, for example, one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

In the second phase, the switches S11, S14, S21, S24, S31, S34, S41, and S44 are turned ON. As a result, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

The first phase and the second phase are repeated as described above. Consequently, for example, when one of the capacitors C12 and C15 is being charged from the node N2, the other of the capacitors C12 and C15 can be discharged to the capacitor C30. That is, the capacitors C12 and C15 are configured to charge and discharge in a complementary manner.

Likewise, as with the set of the capacitors C12 and C15, the set of the capacitors C11 and C14 and the set of the capacitors C13 and C16 are each configured to charge and discharge in a complementary manner as the first phase and the second phase are repeated.

Each of the capacitors C10, C20, C30, and C40 can be configured to function as a smoothing capacitor in an exemplary aspect. That is, the capacitors C10, C20, C30, and C40 are respectively used to hold and smooth the voltages V1 to V4 at the nodes N1 to N4.

The capacitor C10 is connected between the node N1 and ground. Specifically, one of two electrodes of the capacitor C10 is connected to the node N1. The other of the two electrodes of the capacitor C10 is connected to ground.

The capacitor C20 is connected between the nodes N2 and N1. Specifically, one of two electrodes of the capacitor C20 is connected to the node N2. The other of the two electrodes of the capacitor C20 is connected to the node N1.

The capacitor C30 is connected between the nodes N3 and N2. Specifically, one of two electrodes of the capacitor C30 is connected to the node N3. The other of the two electrodes of the capacitor C30 is connected to the node N2.

The capacitor C40 is connected between the nodes N4 and N3. Specifically, one of two electrodes of the capacitor C40 is connected to the node N4. The other of the two electrodes of the capacitor C40 is connected to the node N3.

The switch S11 is an example of a first switch, and is connected between the one of the two electrodes of the capacitor C11 and the node N3. Specifically, the one terminal of the switch S11 is connected to the one of the two electrodes of the capacitor C11. The other terminal of the switch S11 is connected to the node N3. For purposes of the exemplary aspects of the present disclosure, the term “other terminal” can be considered or referred to as a second terminal.

The switch S12 is an example of a third switch, and is connected between the one of the two electrodes of the capacitor C11 and the node N4. Specifically, the one terminal of the switch S12 is connected to the one of the two electrodes of the capacitor C11. The other terminal of the switch S12 is connected to the node N4.

The switch S21 is an example of a fourth switch, and is connected between the one of the two electrodes of the capacitor C12 and the node N2. Specifically, the one terminal of the switch S21 is connected to the one of the two electrodes of the capacitor C12 and the other of the two electrodes of the capacitor C11. The other terminal of the switch S21 is connected to the node N2.

The switch S22 is an example of a second switch, and is connected between the one of the two electrodes of the capacitor C12 and the node N3. Specifically, the one terminal of the switch S22 is connected to the one of the two electrodes of the capacitor C12 and the other of the two electrodes of the capacitor C11. The other terminal of the switch S22 is connected to the node N3.

The switch S31 is connected between the other of the two electrodes of the capacitor C12 and the node N1. Specifically, the one terminal of the switch S31 is connected to the other of the two electrodes of the capacitor C12 and the one of the two electrodes of the capacitor C13. The other terminal of the switch S31 is connected to the node N1.

The switch S32 is connected between the other of the two electrodes of the capacitor C12 and the node N2. Specifically, the one terminal of the switch S32 is connected to the other of the two electrodes of the capacitor C12 and the one of the two electrodes of the capacitor C13. The other terminal of the switch S32 is connected to the node N2. That is, the other terminal of the switch S32 is connected to the other terminal of the switch S21.

The switch S41 is connected between the other of the two electrodes of the capacitor C13 and ground. Specifically, the one terminal of the switch S41 is connected to the other of the two electrodes of the capacitor C13. The other terminal of the switch S41 is connected to ground.

The switch S42 is connected between the other of the two electrodes of the capacitor C13 and the node N1. Specifically, the one terminal of the switch S42 is connected to the other of the two electrodes of the capacitor C13. The other terminal of the switch S42 is connected to the node N1. That is, the other terminal of the switch S42 is connected to the other terminal of the switch S31.

The switch S13 is an example of a fifth switch, and is connected between the one of the two electrodes of the capacitor C14 and the node N3. Specifically, the one terminal of the switch S13 is connected to the one of the two electrodes of the capacitor C14. The other terminal of the switch S13 is connected to the node N3. That is, the other terminal of the switch S13 is connected to the other terminal of the switch S11 and the other terminal of the switch S22.

The switch S14 is an example of a seventh switch, and is connected between the one of the two electrodes of the capacitor C14 and the node N4. Specifically, the one terminal of the switch S14 is connected to the one of the two electrodes of the capacitor C14. The other terminal of the switch S14 is connected to the node N4. That is, the other terminal of the switch S14 is connected to the other terminal of the switch S12.

The switch S23 is an example of an eighth switch, and is connected between the one of the two electrodes of the capacitor C15 and the node N2. Specifically, the one terminal of the switch S23 is connected to one of the two electrodes of the capacitor C15 and the other of the two electrodes of the capacitor C14. The other terminal of the switch S23 is connected to the node N2. That is, the other terminal of the switch S23 is connected to the other terminal of the switch S21 and the other terminal of the switch S32.

The switch S24 is an example of a sixth switch, and is connected between the one of the two electrodes of the capacitor C15 and the node N3. Specifically, the one terminal of the switch S24 is connected to the one of the two electrodes of the capacitor C15 and the other of the two electrodes of the capacitor C14. The other terminal of the switch S24 is connected to the node N3. That is, the other terminal of the switch S24 is connected to the other terminal of the switch S11, the other terminal of the switch S22, and the other terminal of the switch S13.

The switch S33 is connected between the other of the two electrodes of the capacitor C15 and the node N1. Specifically, the one terminal of the switch S33 is connected to the other of the two electrodes of the capacitor C15 and the one of the two electrodes of the capacitor C16. The other terminal of the switch S33 is connected to the node N1. That is, the other terminal of the switch S33 is connected to the other terminal of the switch S31 and the other terminal of the switch S42.

The switch S34 is connected between the other of the two electrodes of the capacitor C15 and the node N2. Specifically, the one terminal of the switch S34 is connected to the other of the two electrodes of the capacitor C15 and the one of the two electrodes of the capacitor C16. The other terminal of the switch S34 is connected to the node N2. That is, the other terminal of the switch S34 is connected to the other terminal of the switch S21, the other terminal of the switch S32, and the other terminal of the switch S23.

The switch S43 is connected between the other of the two electrodes of the capacitor C16 and ground. Specifically, the one terminal of the switch S43 is connected to the other of the two electrodes of the capacitor C16. The other terminal of the switch S43 is connected to ground.

The switch S44 is connected between the other of the two electrodes of the capacitor C16 and the node N1. Specifically, the one terminal of the switch S44 is connected to the other of the two electrodes of the capacitor C16. The other terminal of the switch S44 is connected to the node N1. That is, the other terminal of the switch S44 is connected to the other terminal of the switch S31, the other terminal of the switch S42, and the other terminal of the switch S33.

The switches S11, S12, S13, S14, S21, S22, S23, and S24 correspond to at least one switch included in the switched-capacitor circuit 20.

A first set of switches including the switches S12, S13, S22, S23, S32, S33, S42, and S43, and a second set of switches including the switches S11, S14, S21, S24, S31, S34, S41, and S44 are switched between ON and OFF in a complementary manner based on a control signal S2. Specifically, in the first phase, the switches in the first set are turned ON, and the switches in the second set are turned OFF. Conversely, in the second phase, the switches in the first set are turned OFF, and the switches in the second set are turned ON.

For example, in one of the first and second phases, charging of the capacitors C10 to C40 from the capacitors C11 to C13 is executed, and in the other of the first and second phases, charging of the capacitors C10 to C40 from the capacitors C14 to C16 is executed. That is, the capacitors C10 to C40 are constantly charged from the capacitors C11 to C13 or the capacitors C14 to C16. This ensures that even when current flows rapidly from the nodes N1 to N4 to the output switching circuit 30, the nodes N1 to N4 are rapidly replenished with charge. This configuration in turn reduces fluctuations in potential at the nodes N1 to N4.

The operation mentioned above allows a substantially equal voltage to be maintained across each of the capacitors C10, C20, C30, and C40 in the switched-capacitor circuit 20. Specifically, the voltages V1 to V4 (relative to the ground potential) that satisfy V1:V2:V3:V4 =1:2:3:4 are maintained at the four nodes labeled V1 to V4. The voltage levels of the voltages V1 to V4 correspond to the plurality of discrete levels of voltage that can be supplied by the switched-capacitor circuit 20 to the output switching circuit 30.

The voltage ratio V1:V2:V3:V4 is not limited to 1:2:3:4. For example, the voltage ratio V1:V2:V3:V4 may be 1:2:4:8.

The configuration of the switched-capacitor circuit 20 in FIG. 3 is illustrative and not intended to be limiting. In FIG. 3, the switched-capacitor circuit 20 is configured to supply four discrete levels of voltage. This configuration, however, is not intended to be limiting. The switched-capacitor circuit 20 may be configured to supply any number of discrete levels of voltage greater than or equal to two. For example, in an exemplary aspect, when the switched-capacitor circuit 20 are configured to supply two discrete levels of voltage, it may suffice that the switched-capacitor circuit 20 includes at least the capacitors C12 and C15 and the switches S21 to S24 and S31 to S34.

### 2.2 Circuit Configuration of Output Switching Circuit 30

The circuit configuration of the output switching circuit 30 will now be described with reference to FIG. 3. The output switching circuit 30 is connected to the digital control circuit 60. As illustrated in FIG. 3, the output switching circuit 30 includes input terminals 131 to 134, switches S51 to S54, and an output terminal 130.

The output terminal 130 is connected to an input terminal 140 of the filter circuit 40. The output terminal 130 is a terminal for supplying a power supply voltage selected from among the voltages V1 to V4 to the power amplifier 2 via the filter circuit 40.

The input terminals 131 to 134 are respectively connected to the nodes N4 to N1 of the switched-capacitor circuit 20. The input terminals 131 to 134 are terminals for respectively receiving the voltages V4 to V1 from the switched-capacitor circuit 20.

The switch S51 is an example of a tenth switch, and is connected between the input terminal 131 and the output terminal 130. Specifically, the switch S51 has a terminal connected to the input terminal 131, and a terminal connected to the output terminal 130. With the connection arrangement mentioned above, the switch S51 is switched between ON and OFF based on a control signal S3 to allow switching between connection and disconnection of the input terminal 131 and the output terminal 130 to and from each other.

The switch S52 is an example of a ninth switch, and is connected between the input terminal 132 and the output terminal 130. Specifically, the switch S52 has a terminal connected to the input terminal 132, and a terminal connected to the output terminal 130. With the connection arrangement mentioned above, the switch S52 is switched between ON and OFF based on the control signal S3 to allow switching between connection and disconnection of the input terminal 132 and the output terminal 130 to and from each other.

The switch S53 is connected between the input terminal 133 and the output terminal 130. Specifically, the switch S53 has a terminal connected to the input terminal 133, and a terminal connected to the output terminal 130. With the connection arrangement mentioned above, the switch S53 is switched between ON and OFF based on the control signal S3 to allow switching between connection and disconnection of the input terminal 133 and the output terminal 130 to and from each other.

The switch S54 is connected between the input terminal 134 and the output terminal 130. Specifically, the switch S54 has a terminal connected to the input terminal 134, and a terminal connected to the output terminal 130. With the connection arrangement mentioned above, the switch S54 is switched between ON and OFF based on the control signal S3 to allow switching between connection and disconnection of the input terminal 134 and the output terminal 130 to and from each other.

The switches S51 and S52 correspond to at least one switch included in the output switching circuit 30.

The switches S51 to S54 are controlled to be exclusively ON. That is, only one of the switches S51 to S54 is turned ON, with the remainder of the switches S51 to S54 being turned OFF. This allows the output switching circuit 30 to output one voltage selected from among the voltages V1 to V4

The configuration of the output switching circuit 30 in FIG. 3 is illustrative and not intended to be limiting. In particular, the switches S51 to S54 may have any configuration that allows at least one of the four input terminals 131 to 134 to be selectively connected to the output terminal 130. In one alternative example, the output switching circuit 30 may further include a switch connected between: the switches S51 to S53; and the switch S54 and the output terminal 130. In another alternative example, the output switching circuit 30 may further include a switch connected between: the switches S51 and S52; and the switches S53 and S54 and the output terminal 130.

According to an exemplary aspect, when two discrete levels of voltage are to be supplied from the switched-capacitor circuit 20, the output switching circuit 30 may simply include at least two of the switches S51 to S54.

### 2.3 Circuit Configuration of Pre-Regulator Circuit 10

The configuration of the pre-regulator circuit 10 will now be described with reference to FIG. 3. As illustrated in FIG. 3, the pre-regulator circuit 10 includes an input terminal 110, output terminals 111 to 114, inductor connection terminals 115 and 116, switches S61 to S63, S71 and S72, a power inductor L71, and capacitors C61 to C64.

The input terminal 110 is an input terminal for a DC voltage. That is, the input terminal 110 is a terminal for receiving an input voltage from the DC power source 50.

The output terminal 111 is an output terminal for the voltage V4. That is, the output terminal 111 is a terminal for supplying the voltage V4 to the switched-capacitor circuit 20. The output terminal 111 is connected to the node N4 of the switched-capacitor circuit 20.

The output terminal 112 is an output terminal for the voltage V3. That is, the output terminal 112 is a terminal for supplying the voltage V3 to the switched-capacitor circuit 20. The output terminal 112 is connected to the node N3 of the switched-capacitor circuit 20.

The output terminal 113 is an output terminal for the voltage V2. That is, the output terminal 113 is a terminal for supplying the voltage V2 to the switched-capacitor circuit 20. The output terminal 113 is connected to the node N2 of the switched-capacitor circuit 20.

The output terminal 114 is an output terminal for the voltage V1. That is, the output terminal 114 is a terminal for supplying the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71. For purposes of the exemplary aspects of the present disclosure, the term “one end” can be considered or referred to as a first end. Similarly, the term “other end” can be considered or referred to as a second end.

The switch S71 is an example of an eleventh switch, and is connected between the input terminal 110 and the one end of the power inductor L71. Specifically, the switch S71 has a terminal connected to the input terminal 110, and a terminal connected to the one end of the power inductor L71 via the inductor connection terminal 115. With the connection arrangement mentioned above, the switch S71 is switched between ON and OFF based on a control signal S1 to allow switching between connection and disconnection of the input terminal 110 and the one end of the power inductor L71 to and from each other.

The switch S72 is an example of a twelfth switch, and is connected between the one end of the power inductor L71 and ground. Specifically, the switch S72 has a terminal connected to the one end of the power inductor L71 via the inductor connection terminal 115, and a terminal connected to ground. With the connection arrangement mentioned above, the switch S72 can be switched between ON and OFF based on the control signal S1 to allow switching between connection and disconnection of the one end of the power inductor L71 and ground to and from each other.

The switch S61 is connected between the other end of the power inductor L71 and the output terminal 111. Specifically, the switch S61 has a terminal connected to the other end of the power inductor L71 via the inductor connection terminal 116, and a terminal connected to the output terminal 111. With the connection arrangement mentioned above, the switch S61 can be switched between ON and OFF based on the control signal S1 to allow switching between connection and disconnection of the other one end of the power inductor L71 and the output terminal 111 to and from each other.

The switch S62 is connected between the other end of the power inductor L71 and the output terminal 112. Specifically, the switch S62 has a terminal connected to the other end of the power inductor L71 via the inductor connection terminal 116, and a terminal connected to the output terminal 112. With the connection arrangement mentioned above, the switch S62 can be switched between ON and OFF based on the control signal S1 to allow switching between connection and disconnection of the other one end of the power inductor L71 and the output terminal 112 to and from each other.

The switch S63 is connected between the other end of the power inductor L71 and the output terminal 113. Specifically, the switch S63 has a terminal connected to the other end of the power inductor L71 via the inductor connection terminal 116, and a terminal connected to the output terminal 113. With the connection arrangement mentioned above, the switch S63 can be switched between ON and OFF based on the control signal S1 to allow switching between connection and disconnection of the other one end of the power inductor L71 and the output terminal 113 to and from each other.

The switches S71 and S72 correspond to at least one switch included in the pre-regulator circuit 10.

One of two electrodes of the capacitor C61 is connected to the switch S61 and the output terminal 111. The other of the two electrodes of the capacitor C61 is connected to the switch S62, the output terminal 112, and one of two electrodes of the capacitor C62. The capacitor C61 can be configured to function as a smoothing capacitor in an exemplary aspect.

The one of the two electrodes of the capacitor C62 is connected to the switch S62, the output terminal 112, and the other of the two electrodes of the capacitor C61. The other of the two electrodes of the capacitor C62 is connected to a path that connects the switch S63, the output terminal 113, and one of two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of two electrodes of the capacitor C64.

The one of the two electrodes of the capacitor C64 is connected to the output terminal 114 and the other of the two electrodes of the capacitor C63. The other of the two electrodes of the capacitor C64 is connected to ground.

The switches S61 to S63 are controlled to be exclusively ON. That is, only one of the switches S61 to S63 is turned ON, with the remainder of the switches S61 to S63 being turned OFF. Turning ON only one of the switches S61 to S63 as described above allows the pre-regulator circuit 10 to vary the supply voltage for the switched-capacitor circuit 20 between voltage levels corresponding to the voltages V2 to V4.

The pre-regulator circuit 10 is configured, as described above, to supply charge to the switched-capacitor circuit 20 via at least one of the output terminals 111 to 113.

According to an exemplary aspect, when an input voltage is to be converted into a single first voltage, the pre-regulator circuit 10 may only need to include at least the switches S71 and S72, and the power inductor L71.

### 2.4 Circuit Configuration of Filter Circuit 40

The configuration of the filter circuit 40 will now be described with reference to FIG. 3. As illustrated in FIG. 4, the filter circuit 40 includes inductors L1 and L2, a capacitor C1, a switch SW1, the input terminal 140, and an output terminal 141.

The input terminal 140 is connected to the output terminal 130 of the output switching circuit 30. The input terminal 140 is a terminal for receiving a voltage selected by the output switching circuit 30 from among a plurality of discrete voltages.

The output terminal 141 is an external connection terminal of the tracker circuit 1. The output terminal 141 is connected at a location outside the tracker circuit 1 to the power amplifier 2. The output terminal 141 is a terminal for supplying, to the power amplifier 2, a plurality of discrete voltages VA that have passed through the filter circuit 40.

The inductor L1 is connected between the input terminal 140 and the output terminal 141. That is, the inductor L1 is disposed in series with a path connecting the input terminal 140 and the output terminal 141. Specifically, one end of the inductor L1 is connected to the input terminal 140, and the other end of the inductor L1 is connected to the output terminal 141.

The inductor L2 is connected between a path connecting the inductor L1 and the output terminal 141, and ground. That is, the inductor L2 is connected in shunt with the path connecting the input terminal 140 and the output terminal 141. Specifically, one end of the inductor L2 is connected to a node N42 on the path connecting the inductor L1 and the output terminal 141, and the other end of the inductor L2 is connected to ground via the capacitor C1. The inductor L2 may be connected between the capacitor C1 and ground, and need not necessarily be included in the filter circuit 40.

The capacitor C1 is connected between the inductor L2 and ground. That is, the capacitor C1 is connected in shunt with the path connecting the input terminal 140 and the output terminal 141. Specifically, one end of the capacitor C1 is connected to the inductor L2, and the other end of the capacitor C1 is connected to ground.

The switch SW1 is connected between the input terminal 140 and the output terminal 141, without the inductor L1 being interposed between the switch SW1 and each of these terminals. That is, the switch SW1 is disposed in series with a path located between the input terminal 140 and the output terminal 141 and bypassing the inductor L1. Specifically, one terminal of the switch SW1 is connected to a node N41, which is located on a path connecting the input terminal 140 and the inductor L1, and the other terminal of the switch SW1 is connected to a node N43, which is located on a path connecting the inductor L1 and the output terminal 141.

Although the switch SW1 and the inductor L1 are connected in parallel with each other in FIG. 3, another circuit element may be inserted into the path where the switch SW1 is located, and/or the path where the inductor L1 is located. For example, an inductor may be connected between the switch SW1 and the node N43, and/or between the switch SW1 and the node N41.

In FIG. 3, the node N43, which is connected with the other terminal of the switch SW1, is located between the node N42, which is connected with the inductor L2, and the output terminal 141. The positional relationship between the nodes N42 and N43, however, is not limited to this. In another example, the node N42 may be located between the node N43 and the output terminal 141. In still another example, the node N42 may be located at the same position as the node N43.

The switch SW1 connected as described above is switched between ON and OFF based on a control signal S4. This allows the filter circuit 40 to switch between ON and OFF of a band-reject filter used for removing noise from a plurality of discrete voltages.

The ON/OFF of the band-reject filter described above can be controlled based on, for example, the channel band width (i.e., the modulation band width) of the radio frequency signal RFA. According to an exemplary aspect, when the power amplifier 2 is configured to amplify transmission signals of a plurality of bands, ON/OFF of the switch SW1 may be controlled based on the band of the transmission signal to be amplified by the power amplifier 2. The manner of control of the band-reject filter is not limited to the manner mentioned above.

### 2.5 Circuit Configuration of Digital Control Circuit 60

The circuit configuration of the digital control circuit 60 will now be described. As illustrated in FIG. 4, the digital control circuit 60 includes a first controller 61, a second controller 62, capacitors C81 and C82, and control terminals 601 to 604.

The first controller 61 can be configured to generate the control signals S1, S2, and S4 by processing source-synchronous digital control signals received from the RFIC 5 via the control terminals 601 and 602. The control signal S1 is a signal for controlling the ON/OFF of the switches S61 to S63, S71, and S72 included in the pre-regulator circuit 10. The control signal S2 is a signal for controlling the ON/OFF of the switches S11 to S14, S21 to S24, S31 to S34, and S41 to S44 included in the switched-capacitor circuit 20. The control signal S4 is a signal for controlling the ON/OFF of the switch SW1 included in the filter circuit 40.

The digital control signals to be processed by the first controller 61 are not limited to source-synchronous digital control signals. For example, the first controller 61 may process clock-embedded digital control signals. The first controller 61 may generate a control signal for controlling the output switching circuit 30.

According to the embodiments, a single set of a clock signal and a data signal is used as digital control signals for controlling the pre-regulator circuit 10, the switched-capacitor circuit 20, and the filter circuit 40. This configuration, however, is not intended to be limiting. For example, sets of a clock signal and a data signal may be used individually as digital control signals for controlling the pre-regulator circuit 10, the switched-capacitor circuit 20, and the filter circuit 40.

The second controller 62 generates the control signal S3 by processing digital control logic/line (DCL) signals (DCL1 and DCL2) received from the RFIC 5 via the control terminals 603 and 604. The DCL signals (DCL1 and DCL2) are generated by the RFIC 5 based on, for example, the envelope signal of a radio frequency signal. The control signal S3 is a signal for controlling the ON/OFF of the switches S51 to S54 included in the output switching circuit 30.

The DCL signals (DCL1 and DCL2) are each a 1-bit signal. The voltages V1 to V4 are each represented by a combination of two 1-bit signals. For example, V1, V2, V3, and V4 are represented by “00”, “01”, “10”, and “11”, respectively. Gray code may be used to represent a voltage level.

The capacitor C81 is connected between the first controller 61 and ground. For example, the capacitor C81 is connected between ground and a power supply line that supplies power to the first controller 61, and can be configured to function as a bypass capacitor in an exemplary aspect. The capacitor C82 is connected between the second controller 62 and ground.

According to the embodiments, two DCL signals are used to control the output switching circuit 30. The number of DCL signals, however, is not limited to two. For example, one DCL signal, or any number of DCL signals greater than or equal to three may be used in accordance with the number of voltage levels selectable by each output switching circuit 30. The digital control signal to be used for controlling the output switching circuit 30 is not limited to a DCL signal.

### 3 Implementation Example of Tracker Module 1A according to Example

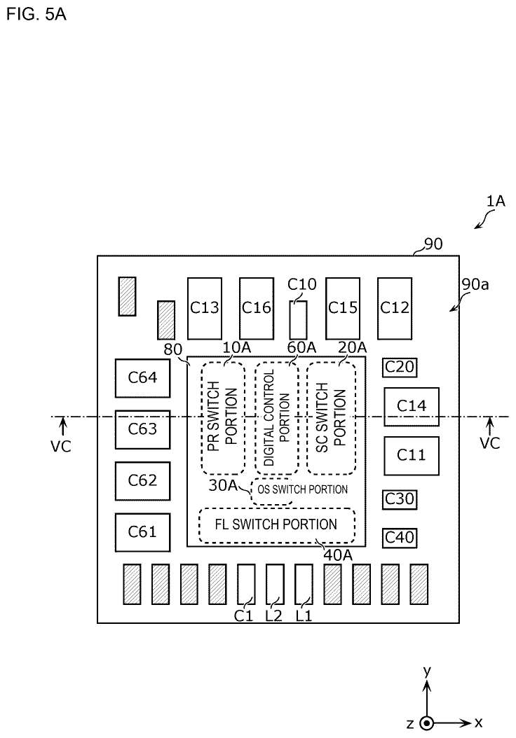

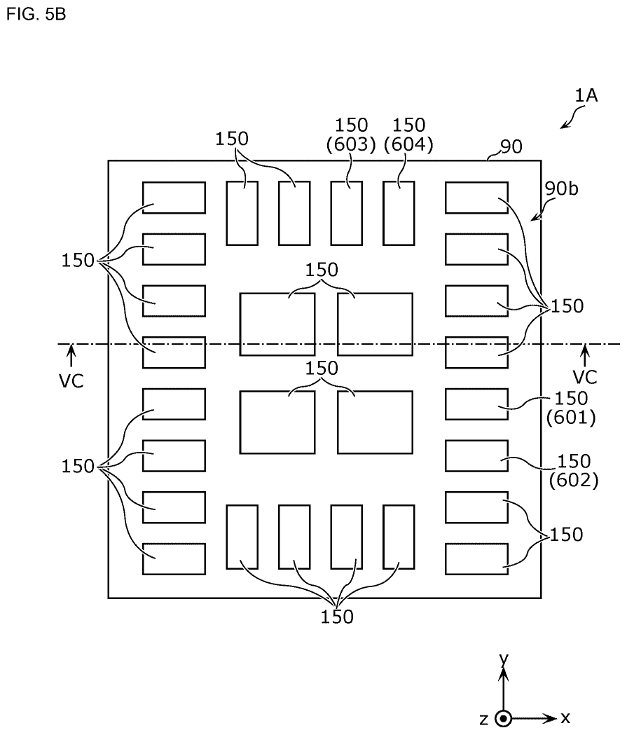

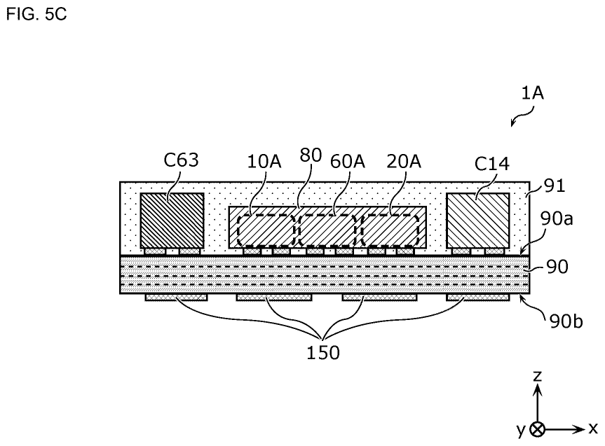

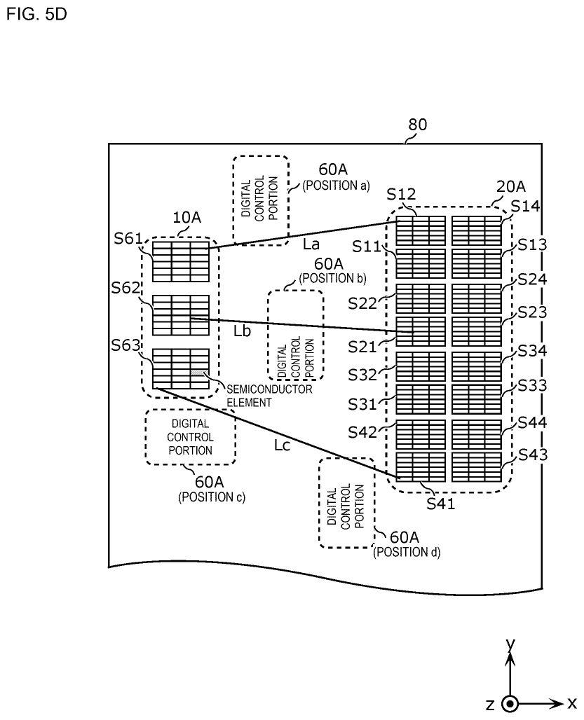

A tracker module 1A will now be described with reference to FIGS. 5A to 5C as an implementation example of the tracker circuit 1 configured as described above.

According to the implementation example and modifications thereof described later, the power inductor L71 included in the pre-regulator circuit 10 is not disposed at a module laminate 90. This configuration, however, is not intended to be limiting. That is, the power inductor L71 may be disposed at the module laminate 90.

FIG. 5A is a plan view of the tracker module 1A according to Example. FIG. 5B is a plan view of the tracker module 1A according to Example. FIG. 5A is a view of a major face 90a of the module laminate 90 as seen from the positive side of the z-axis. FIG. 5B is a see-through view of a major face 90b of the module laminate 90 as seen from the positive side of the z-axis. FIG. 5C is a cross-sectional view of the tracker module 1A according to Example. The cross-section of the tracker module 1A in FIG. 5C is taken along line VC-VC in each of FIGS. 5A and 5B.

In FIGS. 5A to 5C, the illustration of some of wiring lines connecting a plurality of circuit components disposed at the module laminate 90 is omitted. In FIGS. 5A to 5C, the illustration of a resin member 91 covering the plurality of circuit components and a shield electrode layer covering the surface of the resin member 91 is omitted. The resin member 91 and the shield electrode layer need not necessarily be provided. In FIG. 5A, hatched blocks represent optional circuit components that may be omitted in certain exemplary aspects.

As illustrated in FIG. 5A, the tracker module 1A includes the module laminate 90, and an integrated circuit 80.

The module laminate 90 has the major faces 90a and 90b that are opposite to each other. A ground plane or other components are provided in the module laminate 90 and on the major face 90a. Although the module laminate 90 is depicted in FIGS. 5A and 5B as having a rectangular shape in plan view, the shape of the module laminate 90 is not limited to a rectangular shape.

Suitable examples of the module laminate 90 may include, but are not limited to: a low temperature co-fired ceramics (LTCC) substrate or a high temperature co-fired ceramics (HTCC) substrate that has a multilayer structure of a plurality of dielectric layers; a component-embedded substrate; a substrate with a redistribution layer (RDL); and a printed circuit board.

The integrated circuit 80 is disposed at the major face 90a of the module laminate 90. The integrated circuit 80 includes a PR switch portion 10A, an SC switch portion 20A, an OS switch portion 30A, an FL switch portion 40A, and a digital control portion 60A. The PR switch portion 10A includes the switches S61 to S63, S71, and S72 of the pre-regulator circuit 10. The SC switch portion 20A includes the switches S11 to S14, S21 to S24, S31 to S34, and S41 to S44 of the switched-capacitor circuit 20. The OS switch portion 30A includes the switches S51 to S54 of the output switching circuit 30. The FL switch portion 40A includes the switch SW1 of the filter circuit 40. The digital control portion 60A includes the digital control circuit 60.

Although the integrated circuit 80 is depicted in FIG. 5A as having a rectangular shape in plan view of the module laminate 90, the shape of the integrated circuit 80 is not limited to a rectangular shape.

The integrated circuit 80 is implemented by using, for example, complementary metal oxide semiconductor (CMOS). Specifically, the integrated circuit 80 may be manufactured by a silicon on insulator (SOI) process. The integrated circuit 80 is not limited to CMOS.

As illustrated in FIGS. 5A and 5C, with the module laminate 90 seen in plan view (seen in the z-axis direction), the digital control portion 60A is disposed between the PR switch portion 10A and the SC switch portion 20A. In other words, in plan view of the module laminate 90, the digital control circuit 60 is disposed between the plurality of switches included in the pre-regulator circuit 10, and the plurality of switches included in the switched-capacitor circuit 20.

According to the above-mentioned configuration, the digital control circuit 60, which generates a relatively small amount of heat, is disposed between the PR switch portion 10A and the SC switch portion 20A, which are sources of heat generation. This configuration distributes and dissipates the heat generated by the PR switch portion 10A and the SC switch portion 20A. Therefore, efficient heat dissipation with reduced localized temperature rise is achieved. This configuration reduces power consumption of the tracker module 1A, and reduces efficiency degradation of the tracker module 1A.

Further, a sufficient distance can be provided between the PR switch portion 10A and the SC switch portion 20A, which perform switching action. This configuration reduces noise interference caused by the switching action.

According to the embodiments, each of the switches forming the switch portions at least includes two terminals, and one or more semiconductor elements connected between the two terminals. The one or more semiconductor elements are disposed (stacked) in series with a path connecting the two terminals, and are connected in series with each other. In the switch, when the one or more semiconductor elements form a series-connected circuit, a plurality of such series-connected circuits may be connected in parallel between the two terminals. In one example, each of the one or more semiconductor elements is a field effect transistor (FET) including a source electrode, a drain electrode, and a gate electrode. In another example, each of the one or more semiconductor elements may be a bipolar transistor or a diode.

FIG. 5D is a plan view of a portion of the integrated circuit 80 according to Example. FIG. 5D illustrates the integrated circuit 80 as seen from the positive side of the z-axis. As illustrated in FIG. 5D, in each of the switches forming the switch portions, one or more series-connected semiconductor elements are stacked in a direction parallel to the xy-plane, and a plurality of series-connected circuits each including one or more semiconductor elements are disposed in parallel in the direction parallel to the xy-plane. Alternatively, in each of the switches forming the switch portions, one or more series-connected semiconductor elements may be stacked in the z-axis direction, and a plurality of series-connected circuits each including one or more semiconductor elements may be disposed in parallel in the direction parallel to the xy-plane.

As used in the description of the embodiments, expressions such as “circuit A or component A is disposed between a plurality of first switches and a plurality of second switches” can indicate that at least one of a plurality of line segments each connecting a given point within one of the plurality of first switches and a given point within one of the plurality of second switches passes through the circuit A or the component A.

This is explained below with reference to FIG. 5D. The expressions such as “circuit A or component A is disposed between a plurality of first switches and a plurality of second switches” can indicate, for example, that the digital control portion 60A (at any one of Position “a”, Position “b”, Position “c”, and Position “d”) is disposed between the switches S61, S62, and S63 (e.g., a plurality of first switches) of the PR switch portion 10A, and the switches S11 to S14, S21 to S24, S31 to S34, and S41 to S44 (e.g., a plurality of second switches) of the SC switch portion 20A.

Specifically, in one example, in FIG. 5D, a line segment La connects a given point within the switch S61, which is one of the first switches of the PR switch portion 10A, and a given point within the switch S12, which is one of the second switches of the SC switch portion 20A, and the line segment La passes through the digital control portion (at Position “a”). In another example, a line segment Lb connects a given point within the switch S62, which is one of the first switches of the PR switch portion 10A, and a given point within the switch S21, which is one of the second switches of the SC switch portion 20A, and the line segment Lb passes through the digital control portion (at Position “b”). In another example, a line segment Lc connects a given point within the switch S63, which is one of the first switches of the PR switch portion 10A, and a given point within the switch S41, which is one of the second switches of the SC switch portion 20A, and the line segment Lc passes through the digital control portion (at each of Position “c” and Position “d”).

The tracker module 1A further includes the following components in addition to the module laminate 90 and the integrated circuit 80: the capacitors C61 to C64 included in the pre-regulator circuit 10; the capacitors C11 to C16 and the capacitors C10 to C40 included in the switched-capacitor circuit 20; the inductors L1 and L2 and the capacitor C1 included in the filter circuit 40; the resin member 91; and a plurality of external connection terminals 150.

The integrated circuit 80, the capacitors C61 to C64, the capacitors C11 to C16, the capacitors C10 to C40, the inductors L1 and L2, the capacitor C1, and the resin member 91 are disposed on the major face 90a.

The plurality of external connection terminals 150 are disposed on the major face 90b. At least one of the plurality of external connection terminals 150 is connected to the output terminal 141 illustrated in FIG. 3. The plurality of external connection terminals 150 are electrically connected, via connections such as via-conductors provided in the module laminate 90, to the plurality of electronic components disposed on the major face 90a. The plurality of external connection terminals 150 to be used may be, but are not limited to, copper electrodes. For example, the plurality of external connection terminals 150 to be used may be solder electrodes.

The resin member 91 covers the major face 90a, and at least a subset of the plurality of electronic components disposed on the major face 90a. The resin member 91 serves to ensure reliability, such as mechanical strength and moisture resistance, of the plurality of electronic components disposed on the major face 90a. The resin member 91 need not necessarily be included in the tracker module 1A.

The capacitors C61 to C64, the capacitors C11 to C16, and the capacitors C10 to C40 are implemented as chip capacitors according to an exemplary aspect. Moreover, a chip capacitor can refer to a surface mount device (SMD) forming a capacitor. However, it is noted that the plurality of capacitors mentioned above need not necessarily be implemented as chip capacitors. For example, a subset or all of the plurality of capacitors may be included in an integrated passive device (IPD) or may be included in the integrated circuit 80.

The inductors L1 and L2 are implemented as chip inductors according to an exemplary aspect. A chip inductor can refer to an SMD forming an inductor. The inductors L1 and L2 need not necessarily be implemented as chip inductors. For example, a subset or all of the inductors L1 and L2 may be included in an IPD.

The plurality of capacitors and inductors disposed on the major face 90a as described above are grouped for each individual circuit and disposed around the integrated circuit 80.

Specifically, a group of the capacitors C61 to C64 included in the pre-regulator circuit 10 is disposed in a region on the major face 90a located between the following two straight lines in plan view of the module laminate 90: a straight line extending along the left side of the integrated circuit 80; and a straight line extending along the left side of the module laminate 90. The group of circuit components included in the pre-regulator circuit 10 is thus disposed near the PR switch portion 10A located within the integrated circuit 80.

A group of the capacitors C11 to C16 and the capacitors C10 to C40 included in the switched-capacitor circuit 20 is disposed in the following two regions on the major face 90a in plan view of the module laminate 90: a region located between a straight line extending along the top side of the integrated circuit 80 and a straight line extending along the top side of the module laminate 90; and a region located between a straight line extending along the right side of the integrated circuit 80 and a straight line extending along the right side of the module laminate 90. The group of circuit components included in the switched-capacitor circuit 20 is thus disposed near the SC switch portion 20A located within the integrated circuit 80. That is, the SC switch portion 20A is disposed closer to the switched-capacitor circuit 20 than is each of the PR switch portion 10A and the OS switch portion 30A.

A group of the inductors L1 and L2 and the capacitor C1 included in the filter circuit 40 is disposed in a region on the major face 90a located between the following two lines in plan view of the module laminate 90: a straight line extending along the bottom side of the integrated circuit 80; and a straight line extending along the bottom side of the module laminate 90. The group of circuit components included in the filter circuit 40 is thus disposed near the FL switch portion 40A located within the integrated circuit 80. That is, the FL switch portion 40A is disposed closer to the inductors L1 and L2 and the capacitor C1 of the filter circuit 40 than is each of the PR switch portion 10A and the SC switch portion 20A.

The configuration of the tracker module 1A in FIGS. 5A to 5C is illustrative, and not intended to be limiting. For example, as for the capacitors and the inductors disposed on the major face 90a, a subset of these components may be provided in the module laminate 90. In another example, as for the capacitors and the inductors disposed on the major face 90a, a subset of these components need not necessarily be included in the tracker module 1A and need not necessarily be disposed at the module laminate 90.

### 4 Implementation Example of Tracker Module 1B according to Modification 1

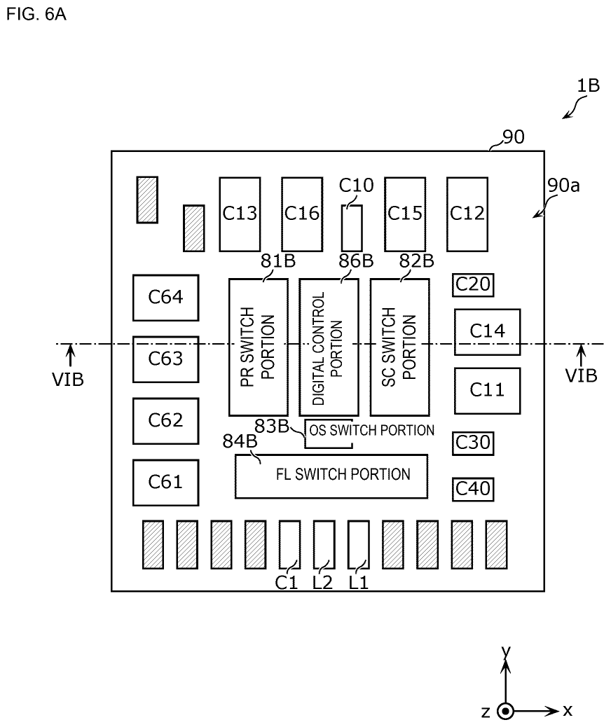

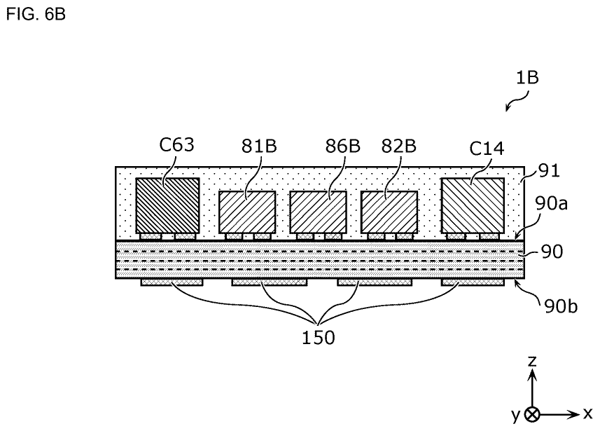

A tracker module 1B according to Modification 1 will now be described with reference to FIGS. 6A and 6B.

FIG. 6A is a plan view of the tracker module 1B according to Modification 1. FIG. 6A is a view of the major face 90a of the module laminate 90 as seen from the positive side of the z-axis. FIG. 6B is a cross-sectional view of the tracker module 1B according to Modification 1. The cross-section of the tracker module 1B in FIG. 6B is taken along line VIB-VIB in FIG. 6A.

As illustrated in FIG. 6A, the tracker module 1B includes the module laminate 90, and integrated circuits 81B, 82B, 83B, 84B, and 86B. The tracker module 1B according to Modification 1 differs from the tracker module 1A according to Example in the presence of a plurality of integrated circuits instead of a single integrated circuit. With regard to the tracker module 1B according to Modification 1, its features identical to those of the tracker module 1A according to Example will not be described in further detail, and the following description will focus mainly on differences from the tracker module 1A.

Each of the integrated circuits 81B, 82B, 83B, 84B, and 86B is disposed at the major face 90a of the module laminate 90.

The integrated circuit 81B is an example of a first integrated circuit. The integrated circuit 81B has the PR switch portion 10A, and includes the switches S61 to S63, and S71 and S72. The integrated circuit 82B is an example of a second integrated circuit. The integrated circuit 82B has the SC switch portion 20A, and includes the switches S11 to S14, S21 to S24, S31 to S34, and S41 to S44. The integrated circuit 83B is an example of a third integrated circuit. The integrated circuit 83B has the OS switch portion 30A and includes the switches S51 to S54. The integrated circuit 84B has the FL switch portion 40A and includes the switch SW1. The integrated circuit 86B includes the digital control circuit 60.

Although the integrated circuits 81B, 82B, 83B, 84B, and 86B are depicted in FIG. 6A as each having a rectangular shape in plan view of the module laminate 90, the shape of these integrated circuits is not limited to a rectangular shape.

The integrated circuits 81B, 82B, 83B, 84B, and 86B are each implemented by using, for example, CMOS. Specifically, each of these integrated circuits may be manufactured by a SOI process. The integrated circuit 80 is not limited to CMOS.

As illustrated in FIGS. 6A and 6B, with the module laminate 90 seen in plan view (seen in the z-axis direction), the integrated circuit 86B is disposed between the integrated circuit 81B and the integrated circuit 82B. In other words, in plan view of the module laminate 90, the digital control circuit 60 is disposed between the plurality of switches included in the pre-regulator circuit 10 and the plurality of switches included in the switched-capacitor circuit 20.

According to the above-mentioned configuration, the integrated circuit 86B (digital control circuit 60), which generates a relatively small amount of heat, is disposed between the integrated circuit 81B (PR switch portion) and the integrated circuit 82B (SC switch portion), which are sources of heat generation. This configuration distributes and dissipates the heat generated by the PR switch portion and the SC switch portion. Therefore, efficient heat dissipation with reduced localized temperature rise is achieved. This configuration reduces efficiency degradation of the tracker module 1B.

Further, a sufficient distance can be provided between the PR switch portion and the SC switch portion, which perform switching action. This configuration reduces noise interference caused by the switching action.

The tracker module 1B includes the following components in addition to the module laminate 90 and the integrated circuit 80: the capacitors C61 to C64 included in the pre-regulator circuit 10; the capacitors C11 to C16 and the capacitors C10 to C40 included in the switched-capacitor circuit 20; the inductors L1 and L2 and the capacitor C1 included in the filter circuit 40; the resin member 91; and the plurality of external connection terminals 150.

The configuration of the tracker module 1B in FIGS. 6A and 6B is illustrative, and not intended to be limiting. For example, as for the capacitors and the inductors disposed on the major face 90a, a subset of these components may be provided in the module laminate 90. In another example, as for the capacitors and the inductors disposed on the major face 90a, a subset of these components need not necessarily be included in the tracker module 1B and need not necessarily be disposed at the module laminate 90.

The FL switch portion may be included in one of the integrated circuits 81B and 82B.

### 5 Implementation Example of Tracker Module 1C according to Modification 2

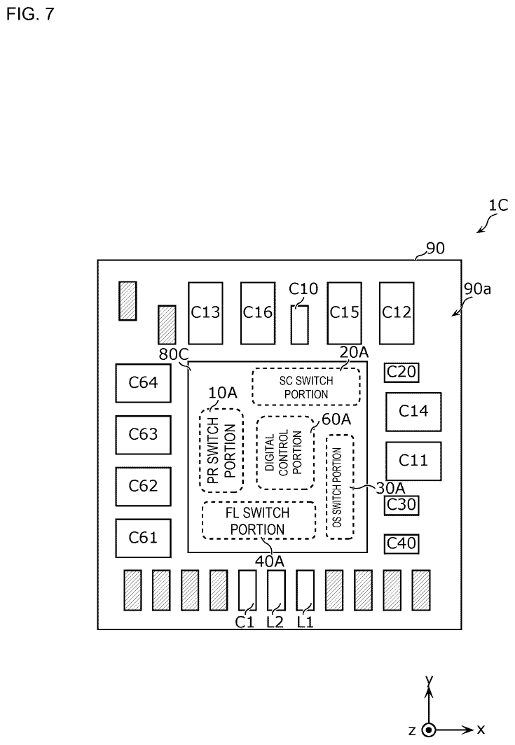

A tracker module 1C according to Modification 2 will now be described with reference to FIG. 7.

FIG. 7 is a plan view of the tracker module 1C according to Modification 2. FIG. 7 is a view of the major face 90a of the module laminate 90 as seen from the positive side of the z-axis.

As illustrated in FIG. 7, the tracker module 1C includes the module laminate 90, and an integrated circuit 80C. The tracker module 1C according to Modification 2 differs from the tracker module 1A according to Example in the positioning of the switch portions within the integrated circuit 80C. With regard to the tracker module 1C according to Modification 2, its features identical to those of the tracker module 1A according to Example will not be described in further detail, and the following description will focus mainly on differences from the tracker module 1A.

The integrated circuit 80C is disposed at the major face 90a of the module laminate 90. The integrated circuit 80C includes the PR switch portion 10A, the SC switch portion 20A, the OS switch portion 30A, the FL switch portion 40A, and the digital control portion 60A. The PR switch portion 10A includes the switches S61 to S63, S71, and S72. The SC switch portion 20A includes the switches S11 to S14, S21 to S24, S31 to S34, and S41 to S44. The OS switch portion 30A includes the switches S51 to S54. The FL switch portion 40A includes the switch SW1. The digital control portion 60A includes the digital control circuit 60.

Although the integrated circuit 80C is depicted in FIG. 7 as having a rectangular shape in plan view of the module laminate 90, the shape of the integrated circuit 80C is not limited to a rectangular shape.

As illustrated in FIG. 7, with the module laminate 90 seen in plan view (seen in the z-axis direction), the digital control portion 60A is disposed between the PR switch portion 10A and the SC switch portion 20A. In other words, in plan view of the module laminate 90, the digital control circuit 60 is disposed between the plurality of switches included in the pre-regulator circuit 10 and the plurality of switches included in the switched-capacitor circuit 20.

With the module laminate 90 seen in plan view (seen in the z-axis direction), the PR switch portion 10A, the SC switch portion 20A, and the OS switch portion 30A are disposed in a peripheral region within the integrated circuit 80C.

As used herein, expressions such as “circuit A or component A is disposed in a peripheral region within the integrated circuit” can indicate that no other circuit component is disposed between one peripheral side of the integrated circuit and the circuit A or component A.

The above-mentioned configuration shortens the heat dissipation path from the PR switch portion 10A and the SC switch portion 20A to an external circuit connected to the tracker module 1C, and consequently improves heat dissipation from the tracker module 1C.

The above-mentioned configuration also shortens the connection wiring between the PR switch portion 10A and the capacitors C61 to C64 included in the pre-regulator circuit 10, and shortens the connection wiring between the SC switch portion 20A, and the capacitors C11 to C16 and the capacitors C10 to C40 included in the switched-capacitor circuit 20. As such, this configuration reduces signal transmission loss.

With the module laminate 90 seen in plan view (seen in the z-axis direction), the digital control portion 60A is disposed more centrally within the integrated circuit 80C than are the PR switch portion 10A, the SC switch portion 20A and the OS switch portion 30A.

According to the above-mentioned configuration, a sufficiently large distance can be provided between the PR switch portion 10A and the SC switch portion 20A, which are sources of heat generation. This configuration distributes and dissipates the heat generated by the PR switch portion 10A and the SC switch portion 20A.

The above-mentioned configuration also shortens the control signal wiring that connects the digital control portion 60A with each of the PR switch portion 10A, the SC switch portion 20A, and the OS switch portion 30A. This enables the digital control circuit 60 to accurately control the switching action of each switch portion.

The tracker module 1C includes the following components in addition to the module laminate 90 and the integrated circuit 80C: the capacitors C61 to C64 included in the pre-regulator circuit 10; the capacitors C11 to C16 and the capacitors C10 to C40 included in the switched-capacitor circuit 20; the inductors L1 and L2 and the capacitor C1 included in the filter circuit 40; the resin member 91; and the plurality of external connection terminals 150.

The configuration of the tracker module 1C in FIG. 7 is illustrative, and not intended to be limiting. For example, as for the capacitors and the inductors disposed on the major face 90a, a subset of these components may be provided in the module laminate 90. In another example, as for the capacitors and the inductors disposed on the major face 90a, a subset of these components need not necessarily be included in the tracker module 1C and need not necessarily be disposed at the module laminate 90.

### 6 Implementation Example of Tracker Module 1D according to Modification 3

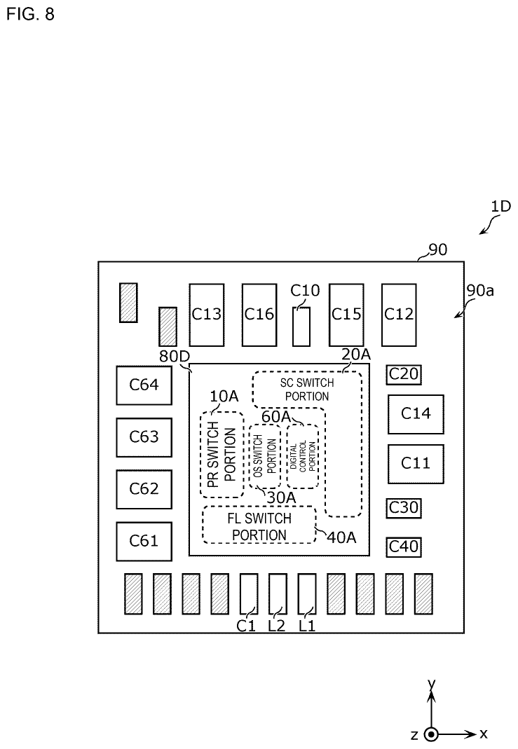

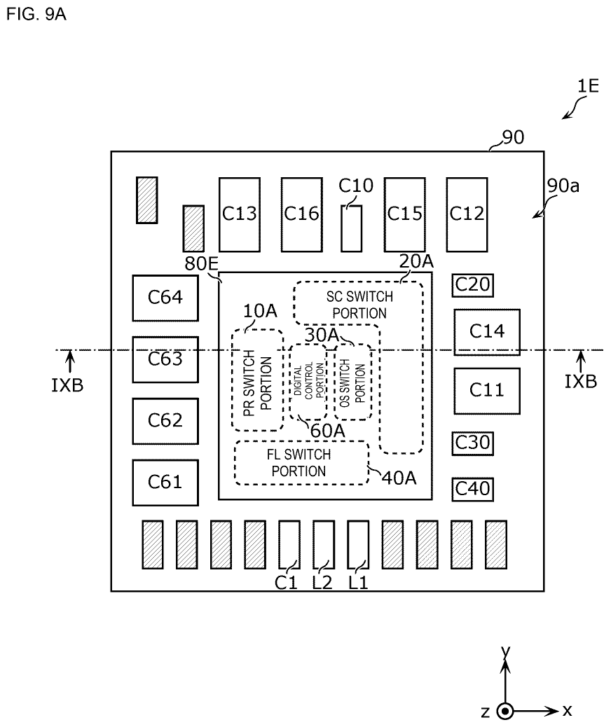

A tracker module 1D according to Modification 3 will now be described with reference to FIG. 8.

FIG. 8 is a plan view of the tracker module 1D according to Modification 3. FIG. 8 is a view of the major face 90a of the module laminate 90 as seen from the positive side of the z-axis.

As illustrated in FIG. 8, the tracker module 1D includes the module laminate 90, and an integrated circuit 80D. The tracker module 1D according to Modification 3 differs from the tracker module 1A according to Example in the positioning of the switch portions within the integrated circuit 80D. With regard to the tracker module 1D according to Modification 3, its features identical to those of the tracker module 1A according to Example will not be described in further detail, and the following description will focus mainly on differences from the tracker module 1A.

The integrated circuit 80D is disposed at the major face 90a of the module laminate 90. The integrated circuit 80D includes the PR switch portion 10A, the SC switch portion 20A, the OS switch portion 30A, the FL switch portion 40A, and the digital control portion 60A. The PR switch portion 10A includes the switches S61 to S63, S71, and S72. The SC switch portion 20A includes the switches S11 to S14, S21 to S24, S31 to S34, and S41 to S44. The OS switch portion 30A includes the switches S51 to S54. The FL switch portion 40A includes the switch SW1. The digital control portion 60A includes the digital control circuit 60.

Although the integrated circuit 80D is depicted in FIG. 8 as having a rectangular shape in plan view of the module laminate 90, the shape of the integrated circuit 80D is not limited to a rectangular shape.

As illustrated in FIG. 8, with the module laminate 90 seen in plan view (seen in the z-axis direction), the SC switch portion 20A is provided in a region formed by two elongated regions extending in mutually intersecting directions (the x-axis direction and the y-axis direction), and the two elongated regions are positioned along two peripheral sides of the integrated circuit 80D (the right and top sides of the integrated circuit 80D). In other words, the SC switch portion 20A is provided in an L-shaped region formed by two elongated regions extending in mutually intersecting directions (the x-axis direction and the y-axis direction) and is disposed in a peripheral region within the integrated circuit 80D.

The above-mentioned configuration shortens the connection wiring between the SC switch portion 20A, and the capacitors C11 to C16 and the capacitors C10 to C40 included in the switched-capacitor circuit 20. This configuration also reduces heat generation in the switched-capacitor circuit 20, and also reduces signal transmission loss.

The tracker module 1D includes the following components in addition to the module laminate 90 and the integrated circuit 80D: the capacitors C61 to C64 included in the pre-regulator circuit 10; the capacitors C11 to C16 and the capacitors C10 to C40 included in the switched-capacitor circuit 20; the inductors L1 and L2 and the capacitor C1 included in the filter circuit 40; the resin member 91; and the plurality of external connection terminals 150.

In the tracker module 1D, the at least one capacitor included in the switched-capacitor circuit 20 may be disposed adjacent to the integrated circuit 80D.

The above-mentioned configuration further shortens the connection wiring between the SC switch portion 20A, and the capacitors C11 to C16 and the capacitors C10 to C40 included in the switched-capacitor circuit 20. This configuration also reduces heat generation in the switched-capacitor circuit 20, and also reduces signal transmission loss.

The configuration of the tracker module 1D in FIG. 8 is illustrative, and not intended to be limiting. For example, as for the capacitors and the inductors disposed on the major face 90a, a subset of these components may be provided in the module laminate 90. In another example, as for the capacitors and the inductors disposed on the major face 90a, a subset of these components need not necessarily be included in the tracker module 1D and need not necessarily be disposed at the module laminate 90.

### 7 Implementation Example of Tracker Module 1E according to Modification 4

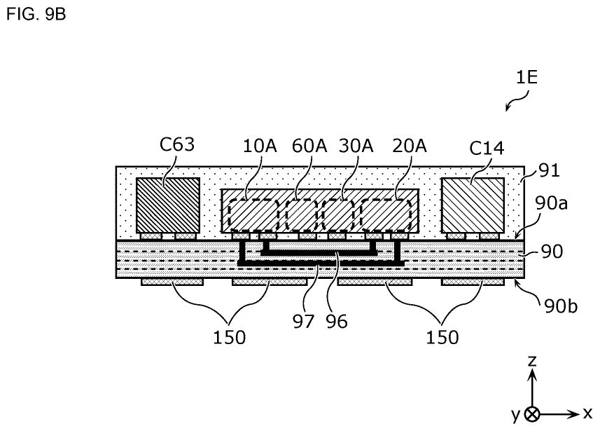

A tracker module 1E according to Modification 4 will now be described with reference to FIGS. 9A and 9B.

FIG. 9A is a plan view of the tracker module 1E according to Modification 4. FIG. 9A is a view of the major face 90a of the module laminate 90 as seen from the positive side of the z-axis. FIG. 9B is a cross-sectional view of the tracker module 1E according to Modification 4. The cross-section of the tracker module 1E in FIG. 9B is taken along line IXB-IXB in FIG. 9A.

As illustrated in FIG. 9A, the tracker module 1E includes the module laminate 90, and an integrated circuit 80E. The tracker module 1E according to Modification 4 differs from the tracker module 1D according to Modification 3 in the positioning of the OS switch portion 30A and the digital control portion 60A. With regard to the tracker module 1E according to Modification 4, its features identical to those of the tracker module 1D according to Modification 3 will not be described in further detail, and the following description will focus mainly on differences from the tracker module 1D.

The integrated circuit 80E is disposed at the major face 90a of the module laminate 90. The integrated circuit 80E includes the PR switch portion 10A, the SC switch portion 20A, the OS switch portion 30A, the FL switch portion 40A, and the digital control portion 60A. The PR switch portion 10A includes the switches S61 to S63, S71, and S72. The SC switch portion 20A includes the switches S11 to S14, S21 to S24, S31 to S34, and S41 to S44. The OS switch portion 30A includes the switches S51 to S54. The FL switch portion 40A includes the switch SW1. The digital control portion 60A includes the digital control circuit 60.

As illustrated in FIGS. 9A and 9B, with the module laminate 90 seen in plan view (seen in the z-axis direction), the digital control portion 60A and the OS switch portion 30A are disposed between the PR switch portion 10A and the SC switch portion 20A. In other words, in plan view of the module laminate 90, the digital control circuit 60, and the plurality of switches included in the output switching circuit 30 are disposed between the plurality of switches included in the pre-regulator circuit 10 and the plurality of switches included in the switched-capacitor circuit 20.

According to the above-mentioned configuration, the digital control circuit 60 and the OS switch portion 30A, which generate a relatively small amount of heat, are disposed between the PR switch portion 10A and the SC switch portion 20A, which are sources of heat generation. This configuration distributes and dissipates the heat generated by the PR switch portion 10A and the SC switch portion 20A. Therefore, efficient heat dissipation with reduced localized temperature rise is achieved. This configuration also further reduces efficiency degradation of the tracker module 1E.

Further, a sufficiently large distance can be provided between the PR switch portion 10A and the SC switch portion 20A, which have a high switching speed relative to the OS switch portion 30A. This configuration further reduces noise interference caused by the switching action.

The SC switch portion 20A and the OS switch portion 30A are disposed adjacent to each other. In other words, the plurality of switches included in the switched-capacitor circuit 20, and the plurality of switches included in the output switching circuit 30 are disposed adjacent to each other.

The above-mentioned configuration connects the SC switch portion 20A and the OS switch portion 30A by low-impedance wiring. This configuration improves transient response performance at the rising and falling voltage edges. Further, the low impedance of the above-mentioned wiring serving as a power line reduces power consumption.

According to the embodiments, expressions such as “a plurality of first switches and a plurality of second switches are disposed adjacent to each other” can indicate that no circuit component is disposed between a given first switch of the plurality of first switches and a given second switch of the plurality of second switches.

As illustrated in FIG. 9B, the PR switch portion 10A and the SC switch portion 20A are connected via conductor wiring lines 96 and 97 provided at the module laminate 90. In other words, the plurality of switches included in the switched-capacitor circuit 20 and the plurality of switches included in the pre-regulator circuit 10 are connected to each other via an electrically conductive member provided at the module laminate 90.

According to the above-mentioned configuration, the wiring for connecting the PR switch portion 10A and the SC switch portion 20A can be provided at the module laminate 90. This configuration improves the freedom of layout of the wiring, and achieves low impedance. Therefore, the signal transmission loss between the PR switch portion 10A and the SC switch portion 20A is reduced.

The tracker module 1E includes the following components in addition to the module laminate 90 and the integrated circuit 80E: the capacitors C61 to C64 included in the pre-regulator circuit 10; the capacitors C11 to C16 and the capacitors C10 to C40 included in the switched-capacitor circuit 20; the inductors L1 and L2 and the capacitor C1 included in the filter circuit 40; the resin member 91; and the plurality of external connection terminals 150.

In the tracker module 1E, the at least one capacitor included in the switched-capacitor circuit 20 may be disposed adjacent to the integrated circuit 80E.

According to the above-mentioned configuration, the wiring for connecting the PR switch portion 10A and the SC switch portion 20A can be provided at the module laminate 90. This configuration improves the freedom of layout of the wiring and achieve low impedance. Therefore, the signal transmission loss between the pre-regulator circuit 10 and the switched-capacitor circuit 20 is reduced.

The configuration of the tracker module 1E in FIGS. 9A and 9B is illustrative, and not intended to be limiting. For example, as for the capacitors and the inductors disposed on the major face 90a, a subset of these components may be provided in the module laminate 90. In another example, as for the capacitors and the inductors disposed on the major face 90a, a subset of these components need not necessarily be included in the tracker module 1E and need not necessarily be disposed at the module laminate 90.

### 8 Implementation Example of Tracker Module 1F according to Modification 5

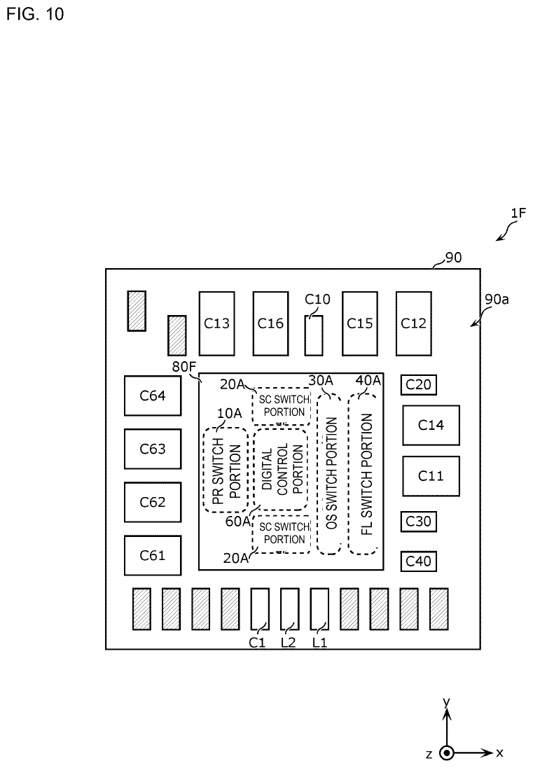

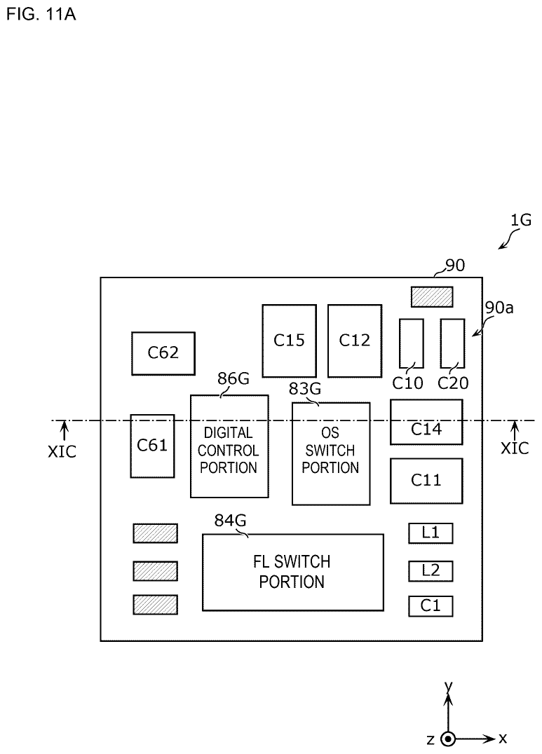

A tracker module 1F according to Modification 5 will now be described with reference to FIG. 10.

FIG. 10 is a plan view of the tracker module 1F according to Modification 5. FIG. 10 is a view of the major face 90a of the module laminate 90 as seen from the positive side of the z-axis.

As illustrated in FIG. 10, the tracker module 1F includes the module laminate 90, and an integrated circuit 80F. The tracker module 1F according to Modification 5 differs from the tracker module 1A according to Example in the positioning of the switch portions in the integrated circuit 80F. With regard to the tracker module 1F according to Modification 5, its features identical to those of the tracker module 1A according to Example will not be described in further detail, and the following description will focus mainly on differences from the tracker module 1A.

The integrated circuit 80F is disposed at the major face 90a of the module laminate 90. The integrated circuit 80F includes the PR switch portion 10A, the SC switch portion 20A, the OS switch portion 30A, the FL switch portion 40A, and the digital control portion 60A. The PR switch portion 10A includes the switches S61 to S63, S71, and S72. The SC switch portion 20A includes the switches S11 to S14, S21 to S24, S31 to S34, and S41 to S44. The OS switch portion 30A includes the switches S51 to S54. The FL switch portion 40A includes the switch SW1. The digital control portion 60A includes the digital control circuit 60.

As illustrated in FIG. 10, the SC switch portion 20A is disposed separately in two regions that are spaced apart from each other. In other words, the plurality of switches included in the switched-capacitor circuit 20 are provided separately in a first region and a second region that are spaced apart from each other.

According to the above-mentioned configuration, the SC switch portion 20A, which is a source of heat generation, is provided separately in two regions. This configuration distributes and dissipates the heat generated by the SC switch portion 20A.

With the module laminate 90 seen in plan view (seen in the z-axis direction), the digital control portion 60A is disposed between the two separately disposed SC switch portions 20A.

According to the above-mentioned configuration, the digital control circuit 60, which generates a relatively small amount of heat, is disposed between the two SC switch portions 20A, which are sources of heat generation. This configuration distributes and dissipates the heat generated by the SC switch portions 20A. Therefore, efficient heat dissipation with reduced localized temperature rise is achieved. This configuration further reduces efficiency degradation of the tracker module 1F.

The tracker module 1F includes the following components in addition to the module laminate 90 and the integrated circuit 80F: the capacitors C61 to C64 included in the pre-regulator circuit 10; the capacitors C11 to C16 and the capacitors C10 to C40 included in the switched-capacitor circuit 20; the inductors L1 and L2 and the capacitor C1 included in the filter circuit 40; the resin member 91; and the plurality of external connection terminals 150.

The configuration of the tracker module 1F in FIG. 10 is illustrative, and not intended to be limiting. For example, as for the capacitors and the inductors disposed on the major face 90a, a subset of these components may be provided in the module laminate 90. In another example, as for the capacitors and the inductors disposed on the major face 90a, a subset of these components need not necessarily be included in the tracker module 1F and need not necessarily be disposed at the module laminate 90.

### 9 Implementation Example of Tracker Module 1G according to Modification 6

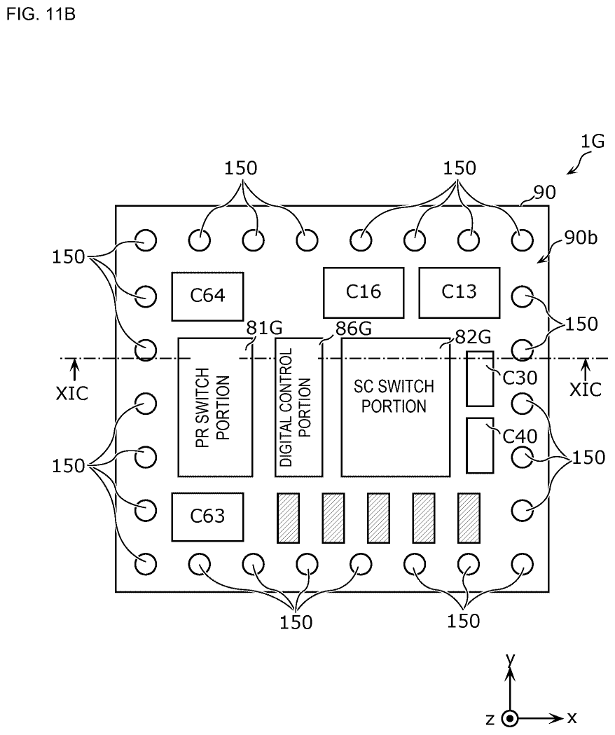

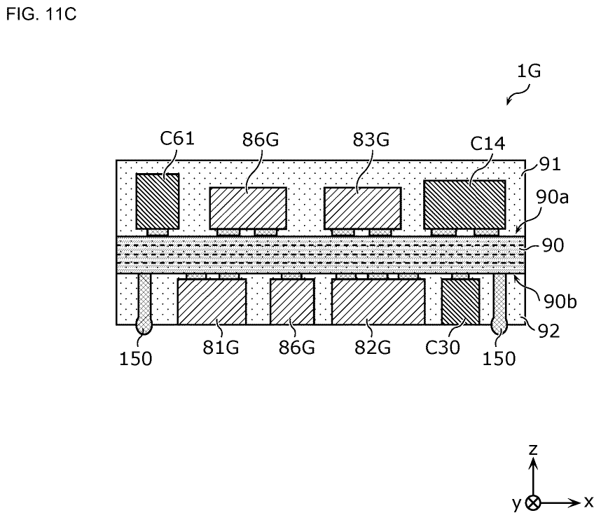

A tracker module 1G according to Modification 6 will now be described with reference to FIGS. 11A to 11C.

FIG. 11A is a plan view of the tracker module 1G according to Modification 6. FIG. 11B is a plan view of the tracker module 1G according to Modification 6. FIG. 11A is a view of the major face 90a of the module laminate 90 as seen from the positive side of the z-axis. FIG. 11B is a see-through view of the major face 90b of the module laminate 90 as seen from the positive side of the z-axis. FIG. 11C is a cross-sectional view of the tracker module 1G according to Modification 6. The cross-section of the tracker module 1G in FIG. 11C is taken along line XIC-XIC in each of FIGS. 11A and 11B.

As illustrated in FIGS. 11A and 11B, the tracker module 1G includes the module laminate 90, and integrated circuits 81G, 82G, 83G, 84G, and 86G. The tracker module 1G according to Modification 6 differs from the tracker module 1A according to Example in that a plurality of integrated circuits are disposed on the major faces 90a and 90b of the module laminate 90 in a distributed manner. With regard to the tracker module 1G according to Modification 6, its features identical to those of the tracker module 1A according to Example will not be described in further detail, and the following description will focus mainly on differences from the tracker module 1A.

Each of the integrated circuits 83G, 84G, and 86G is disposed at the major face 90a of the module laminate 90. Each of the integrated circuits 81G, 82G, and 86G is disposed at the major face 90b of the module laminate 90.

The integrated circuit 81G is an example of the first integrated circuit. The integrated circuit 81G has the PR switch portion 10A, and includes the switches S61 to S63, and S71 and S72. The integrated circuit 82G is an example of the second integrated circuit. The integrated circuit 82G has the SC switch portion 20A, and includes the switches S11 to S14, S21 to S24, S31 to S34, and S41 to S44. The integrated circuit 83G is an example of the third integrated circuit. The integrated circuit 83G has the OS switch portion 30A and includes the switches S51 to S54. The integrated circuit 84G has the FL switch portion 40A and includes the switch SW1. The integrated circuit 86G includes the digital control circuit 60.

Although the integrated circuits 81G, 82G, 83G, 84G, and 86G are depicted in FIGS. 11A and 11B as each having a rectangular shape in plan view of the module laminate 90, the shape of these integrated circuits is not limited to a rectangular shape.

The tracker module 1G includes the following components in addition to the module laminate 90 and the plurality of integrated circuits mentioned above: the capacitors C61 to C64 included in the pre-regulator circuit 10; the capacitors C11 to C16 and the capacitors C10 to C40 included in the switched-capacitor circuit 20; the inductors L1 and L2 and the capacitor C1 included in the filter circuit 40; resin members 91 and 92; and the plurality of external connection terminals 150.

In addition to the integrated circuits 83G, 84G, and 86G, the following components are disposed on the major face 90a: the capacitors C61 to C62, the capacitors C11, C12, C14 and C15, the capacitors C10 to C20, the inductors L1 and L2, the capacitor C1, and the resin member 91.

In addition to the integrated circuits 81G, 82G, and 86G, the following components are disposed on the major face 90b: the capacitors C63 and C64, the capacitors C13 and C16, the capacitors C30 and C40, and the plurality of external connection terminals 150. At least one of the plurality of external connection terminals 150 is connected to the output terminal 141 illustrated in FIG. 3. The plurality of external connection terminals 150 are electrically connected, via connections such as via-conductors provided in the module laminate 90, to the plurality of electronic components disposed on the major faces 90a and 90b and are connected to an electrode on a motherboard disposed near the major face 90b.

The resin member 91 covers at least a subset of the plurality of electronic components disposed on the major face 90a. The resin member 91 serves to ensure reliability, such as mechanical strength and moisture resistance, of the plurality of electronic components disposed on the major face 90a. The resin member 92 covers at least a subset of the plurality of electronic components disposed on the major face 90b. The resin member 92 serves to ensure reliability, such as mechanical strength and moisture resistance, of the plurality of electronic components disposed on the major face 90b. The resin members 91 and 92 need not necessarily be included in the tracker module 1G.

According to the above-mentioned configuration, the integrated circuit 81G (PR switch portion) and the integrated circuit 82G (SC switch portion), which are sources of heat generation, are disposed at the major face 90b. This configuration shortens the heat dissipation path to the motherboard (e.g., an external circuit), and also improves heat dissipation from the back side of the integrated circuits 81G and 82G. Therefore, efficient heat dissipation with reduced temperature rise of the tracker module 1G is achieved. This configuration also reduces efficiency degradation of the tracker module 1G.

The integrated circuit 83G is disposed at the major face 90a, and with the module laminate 90 seen in plan view (seen in the z-axis direction), the integrated circuit 82G and the integrated circuit 83G at least partially overlap each other.

The above-mentioned configuration connects the SC switch portion and the OS switch portion by low-impedance wiring. This configuration improves transient response performance at the rising and falling voltage edges. Further, the low impedance of the above-mentioned wiring serving as a power line reduces power consumption.

The configuration of the tracker module 1G in FIGS. 11A to 11C is illustrative, and not intended to be limiting. For example, as for the capacitors and the inductors disposed on the major faces 90a and 90b, a subset of these components may be provided in the module laminate 90. In another example, as for the capacitors and the inductors disposed on the major faces 90a and 90b, a subset of these components need not necessarily be included in the tracker module 1G and need not necessarily be disposed at the module laminate 90.

### 10 Technical Effects

As described above, the tracker modules 1A and 1C to 1F according to Example and its modifications include the module laminate 90, and a single integrated circuit 80 (or 80C, 80D, 80E, or 80F) disposed at the module laminate 90. The integrated circuit 80 (or 80C, 80D, 80E, or 80F) includes: at least one switch included in the pre-regulator circuit 10, the pre-regulator circuit 10 being configured to convert an input voltage into a first voltage; at least one switch included in the switched-capacitor circuit 20, the switched-capacitor circuit 20 being configured to generate a plurality of discrete second voltages based on the first voltage; at least one switch included in the output switching circuit 30, the output switching circuit 30 being configured to selectively output at least one of the plurality of discrete second voltages generated by the switched-capacitor circuit 20; and the digital control circuit 60 configured to, based on a digital control signal corresponding to an envelope signal, cause the output switching circuit 30 to selectively output at least one of the plurality of discrete second voltages. In plan view of the module laminate 90, at least one of: the at least one switch included in the output switching circuit 30; or the digital control circuit 60 is disposed between the at least one switch included in the pre-regulator circuit 10 and the at least one switch included in the switched-capacitor circuit 20.

According to the above-mentioned configuration, at least one of the digital control circuit 60 or the OS switch portion 30A, which generates a relatively small amount of heat, is disposed between the PR switch portion 10A and the SC switch portion 20A, which are sources of heat generation. This configuration distributes and dissipates the heat generated by the PR switch portion 10A and the SC switch portion 20A. Therefore, efficient heat dissipation with reduced localized temperature rise is achieved. This configuration also reduces efficiency degradation of the tracker modules 1A, and 1C to 1F.

The tracker modules 1B and 1G according to modifications include: the module laminate 90; the integrated circuit 81B (or 81G) disposed at the module laminate 90 and including at least one switch included in the pre-regulator circuit 10, the pre-regulator circuit 10 being configured to convert an input voltage into a first voltage; the integrated circuit 82B (or 82G) disposed at the module laminate 90 and including at least one switch included in the switched-capacitor circuit 20, the switched-capacitor circuit 20 being configured to generate a plurality of discrete second voltages based on the first voltage; the integrated circuit 83B (or 83G) disposed at the module laminate 90 and including at least one switch included in the output switching circuit 30, the output switching circuit 30 being configured to selectively output at least one of the plurality of discrete second voltages generated by the switched-capacitor circuit 20; and the digital control circuit 60 configured to, based on a digital control signal corresponding to an envelope signal, cause the output switching circuit 30 to selectively output at least one of the plurality of discrete second voltages. In plan view of the module laminate 90, at least one of: the at least one switch included in the output switching circuit 30; or the digital control circuit 60 is disposed between the at least one switch included in the pre-regulator circuit 10 and the at least one switch included in the switched-capacitor circuit 20.

According to the above-mentioned configuration, at least one of the digital control circuit 60 or the OS switch portion 30A, which generates a relatively small amount of heat, is disposed between the PR switch portion 10A and the SC switch portion 20A, which are sources of heat generation. This configuration distributes and dissipates the heat generated by the PR switch portion 10A and the SC switch portion 20A. Therefore, efficient heat dissipation with reduced localized temperature rise is achieved. This configuration also reduces efficiency degradation of the tracker modules 1B and 1G.

In one exemplary configuration of the tracker module 1G, the module laminate 90 has the major faces 90a and 90b that are opposite to each other, the tracker module 1G further includes the external connection terminal 150 disposed at the major face 90b, and the integrated circuits 81G and 82G are disposed at the major face 90b.

According to the above-mentioned configuration, the integrated circuit 81G (PR switch portion) and the integrated circuit 82G (SC switch portion), which are sources of heat generation, are disposed at the major face 90b. This configuration shortens the heat dissipation path to the motherboard (e.g., an external circuit), and also improve heat dissipation from the back side of the integrated circuits 81G and 82G. Therefore, efficient heat dissipation with reduced temperature rise of the tracker module 1G is achieved. This configuration also reduces efficiency degradation of the tracker module 1G.

In one exemplary configuration of the tracker module 1G, the integrated circuit 83G is disposed at the major face 90a, and in plan view of the module laminate 90, the integrated circuit 82G and the integrated circuit 83G at least partially overlap each other.

The above-mentioned configuration connects the SC switch portion 20A and the OS switch portion 30A by low-impedance wiring. This configuration also improves transient response performance at the rising and falling voltage edges. Further, the low impedance of the above-mentioned wiring serving as a power line reduces power consumption.

In one exemplary configuration of the tracker modules 1E and 1F, the at least one switch included in the switched-capacitor circuit 20, and the at least one switch included in the output switching circuit 30 are disposed adjacent to each other.

The above-mentioned configuration connects the SC switch portion 20A and the OS switch portion 30A by low-impedance wiring. This configuration also improves transient response performance at the rising and falling voltage edges. Further, the low impedance of the above-mentioned wiring serving as a power line reduces power consumption.

In one exemplary configuration of the tracker modules 1D and 1E, in plan view of the module laminate 90, the at least one switch included in the output switching circuit 30, and the digital control circuit 60 are disposed between the at least one switch included in the pre-regulator circuit 10 and the at least one switch included in the switched-capacitor circuit 20.

According to the above-mentioned configuration, the digital control circuit 60 and the OS switch portion 30A, which generate a relatively small amount of heat, are disposed between the PR switch portion 10A and the SC switch portion 20A, which are sources of heat generation. This configuration distributes and dissipates the heat generated by the PR switch portion 10A and the SC switch portion 20A. Therefore, efficient heat dissipation with reduced localized temperature rise is achieved. This configuration further reduces efficiency degradation of the tracker modules 1D and 1E.

In one exemplary configuration of the tracker module 1C, in plan view of the module laminate 90, the at least one switch included in the pre-regulator circuit 10, the at least one switch included in the switched-capacitor circuit 20, and the at least one switch included in the output switching circuit 30 are disposed in a peripheral region within the integrated circuit 80C.

The above-mentioned configuration shortens the heat dissipation path from the PR switch portion 10A and the SC switch portion 20A to an external circuit connected to the tracker module 1C, and consequently improve heat dissipation from the tracker module 1C. The above-mentioned configuration also shortens the connection wiring between the PR switch portion 10A and the capacitors included in the pre-regulator circuit 10, and to shorten the connection wiring between the SC switch portion 20A and the capacitors included in the switched-capacitor circuit 20. This configuration reduces signal transmission loss.

In one exemplary configuration of the tracker module 1C, in plan view of the module laminate 90, the digital control circuit 60 is disposed more centrally within the integrated circuit 80C than are the at least one switch included in the pre-regulator circuit 10, the at least one switch included in the switched-capacitor circuit 20, and the at least one switch included in the output switching circuit 30.

According to the above-mentioned configuration, a sufficient distance can be provided between the PR switch portion 10A and the SC switch portion 20A, which are sources of heat generation. This configuration distributes and dissipates the heat generated by the PR switch portion 10A and the SC switch portion 20A. The above-mentioned configuration also shortens the control signal wiring that connects the digital control portion 60A with each of the PR switch portion 10A, the SC switch portion 20A, and the OS switch portion 30A. This configuration enables the digital control circuit 60 to accurately control the switching action of each switch portion.

In one exemplary configuration of the tracker modules 1D and 1E, in plan view of the module laminate 90, the at least one switch included in the switched-capacitor circuit 20 is provided in a region formed by two elongated regions extending in mutually intersecting directions, and the two elongated regions are positioned along two peripheral sides of the integrated circuit 80D (or 80E).

The above-mentioned configuration shortens the connection wiring between the SC switch portion 20A and the capacitors included in the switched-capacitor circuit 20. This configuration reduces heat generation in the switched-capacitor circuit 20, and also reduces signal transmission loss.

In one exemplary configuration of the tracker modules 1D and 1E, the at least one capacitor included in the switched-capacitor circuit 20 may be disposed adjacent to the integrated circuit 80D (or 80E).

The above-mentioned configuration further shortens the connection wiring between the SC switch portion 20A and the capacitors included in the switched-capacitor circuit 20. This configuration reduces heat generation in the switched-capacitor circuit 20, and also reduces signal transmission loss.

In one exemplary configuration of the tracker module 1F, the at least one switch included in the switched-capacitor circuit 20 is provided separately in a first region and a second region that are spaced apart from each other.

According to the above-mentioned configuration, the SC switch portion 20A, which is a source of heat generation, is provided separately in two regions. This configuration distributes and dissipates the heat generated by the SC switch portion 20A.

In one exemplary configuration of the tracker module 1F, in plan view of the module laminate 90, the digital control circuit 60 is disposed between the first region and the second region.

According to the above-mentioned configuration, the digital control circuit 60, which generates a relatively small amount of heat, is disposed between the two SC switch portions 20A, which are sources of heat generation. This configuration distributes and dissipates the heat generated by the SC switch portions 20A. Therefore, efficient heat dissipation with reduced localized temperature rise is achieved. This configuration further reduces efficiency degradation of the tracker module 1F.

In one exemplary configuration of the tracker module 1E, a switch included in the switched-capacitor circuit 20 and a switch included in the pre-regulator circuit 10 are connected to each other via the conductor wiring line 96 provided at the module laminate 90.

According to the above-mentioned configuration, the wiring for connecting the PR switch portion 10A and the SC switch portion 20A can be provided at the module laminate 90. This configuration improves the freedom of layout of the wiring and achieve low impedance. Therefore, the signal transmission loss between the PR switch portion 10A and the SC switch portion 20A is reduced.

In one exemplary configuration of the tracker module 1E, the at least one capacitor included in the switched-capacitor circuit 20 is disposed adjacent to the integrated circuit 80D (or 80E).

According to the above-mentioned configuration, the wiring for connecting the PR switch portion 10A and the SC switch portion 20A can be provided at the module laminate 90. This configuration improves the freedom of layout of the wiring and achieve low impedance. Therefore, the signal transmission loss between the pre-regulator circuit 10 and the switched-capacitor circuit 20 is reduced.

The tracker modules 1A, and 1C to 1F according to Example and its modifications include the module laminate 90, and a single integrated circuit 80 (or 80C, 80D, 80E, or 80F) disposed at the module laminate 90. The integrated circuit 80 (or 80C, 80D, 80E, or 80F) includes: a first switch, a second switch, a third switch, a fourth switch, a fifth switch, a sixth switch, a seventh switch, and an eighth switch that are included in the switched-capacitor circuit 20; a ninth switch and a tenth switch that are included in the output switching circuit 30 connected to the switched-capacitor circuit 20; an eleventh switch and a twelfth switch that are included in the pre-regulator circuit 10 connected to the switched-capacitor circuit 20; and the digital control circuit 60 configured to control the first to twelfth switches. The switched-capacitor circuit 20 includes: a first capacitor having a first electrode and a second electrode; a second capacitor having a third electrode and a fourth electrode; and the first to eighth switches. One terminal of the first switch and one terminal of the third switch are connected to the first electrode. One terminal of the second switch and one terminal of the fourth switch are connected to the second electrode. One terminal of the fifth switch and one terminal of the seventh switch are connected to the third electrode. One terminal of the sixth switch and one terminal of the eighth switch are connected to the fourth electrode. Another terminal (e.g., a second terminal) of the first switch, another terminal of the second switch, another terminal of the fifth switch, and another terminal of the sixth switch are connected to each other. Another terminal of the third switch is connected to an other terminal of the seventh switch. Another terminal of the fourth switch is connected to another terminal of the eighth switch. The output switching circuit 30 includes: a first output terminal; the ninth switch connected between the first output terminal, and the other terminal of the first switch, the other terminal of the second switch, the other terminal of the fifth switch, and the other terminal of the sixth switch; and the tenth switch connected between the first output terminal, and the other terminal of the third switch and the other terminal of the seventh switch. The pre-regulator circuit 10 includes: an input terminal; the eleventh switch connected between the input terminal and one end of a power inductor; and the twelfth switch connected between the one end of the power inductor and ground. Another end of the power inductor is connected to the other terminal of the first switch, the other terminal of the second switch, the other terminal of the fifth switch, and the other terminal of the sixth switch. In plan view of the module laminate 90, at least one of: the ninth switch and the tenth switch: or the digital control circuit 60 is disposed between: the eleventh switch and the twelfth switch; and the first switch, the second switch, the third switch, the fourth switch, the fifth switch, the sixth switch, the seventh switch, and the eighth switch.

According to the above-mentioned configuration, at least one of the digital control circuit 60 or the OS switch portion 30A, which generates a relatively small amount of heat, is disposed between the PR switch portion 10A and the SC switch portion 20A, which are sources of heat generation. This configuration distributes and dissipates the heat generated by the PR switch portion 10A and the SC switch portion 20A. Therefore, efficient heat dissipation with reduced localized temperature rise is achieved. This configuration reduces efficiency degradation of the tracker modules 1A, and 1C to 1F.

In one exemplary configuration of the tracker modules 1E and 1F, the first to eighth switches are disposed adjacent to the ninth and tenth switches.

The above-mentioned configuration connects the SC switch portion 20A and the OS switch portion 30A by low-impedance wiring. This configuration improves transient response performance at the rising and falling voltage edges. Further, the low impedance of the above-mentioned wiring serving as a power line also reduce power consumption.

In one exemplary configuration of the tracker module 1C, in plan view of the module laminate 90, the first to twelfth switches are disposed in a peripheral region within the integrated circuit 80C.

The above-mentioned configuration shortens the heat dissipation path from the PR switch portion 10A and the SC switch portion 20A to an external circuit connected to the tracker module 1C, and consequently improves heat dissipation from the tracker module 1C. The above-mentioned configuration also shortens the connection wiring between the PR switch portion 10A and the capacitors included in the pre-regulator circuit 10, and shortens the connection wiring between the SC switch portion 20A and the capacitors included in the switched-capacitor circuit 20. This configuration reduces signal transmission loss.

In one exemplary configuration of the tracker module 1C, in plan view of the module laminate 90, the digital control circuit 60 is disposed more centrally within the integrated circuit 80C than are the first to twelfth switches.

According to the above-mentioned configuration, a sufficient distance can be provided between the PR switch portion 10A and the SC switch portion 20A, which are sources of heat generation. This configuration distributes and dissipates the heat generated by the PR switch portion 10A and the SC switch portion 20A. The above-mentioned configuration also shortens the control signal wiring that connects the digital control portion 60A with each of the PR switch portion 10A, the SC switch portion 20A, and the OS switch portion 30A. This configuration enables the digital control circuit 60 to accurately control the switching action of each switch portion.

In one exemplary configuration of the tracker modules 1D and 1E, in plan view of the module laminate 90, the first to eighth switches are provided in a region formed by two elongated regions extending in mutually intersecting directions, and the two elongated regions are positioned along two peripheral sides of the integrated circuit 80D (or 80E).

The above-mentioned configuration shortens the connection wiring between the SC switch portion 20A and the capacitors included in the switched-capacitor circuit 20. This configuration also reduces heat generation in the switched-capacitor circuit 20, and also reduces signal transmission loss.

In one exemplary configuration of the tracker module 1E, at least one of the first to eighth switches, and at least one of the eleventh or twelfth switches are connected to each other via the conductor wiring line 96 provided at the module laminate 90.

According to the above-mentioned configuration, the conductor wiring line for connecting the PR switch portion 10A and the SC switch portion 20A can be provided at the module laminate 90. This configuration improves the freedom of layout of the conductor wiring line and achieve low impedance. Therefore, the signal transmission loss between the pre-regulator circuit 10 and the switched-capacitor circuit 20 is reduced.

### Additional Exemplary Embodiments

Although the tracker module according to the exemplary aspects of the present disclosure has been described above based on embodiments, the embodiments are not intended to limit the tracker module. The exemplary aspects of the present disclosure are intended to also encompass: other embodiments implemented by combining any constituent elements in the above embodiments; modifications obtained by modifying the above embodiments in various ways as may become apparent to those skilled in the art without departing from the scope of the exemplary aspects; and various devices incorporating the tracker module mentioned above.

For example, in the circuit configurations of the various circuits according to the above embodiments, another circuit element, a wiring line, and other features may be inserted between individual circuit elements and paths connecting signal paths disclosed in the drawings. For example, an impedance matching circuit may be inserted between the power amplifier 2 and the filter 3.

According to the above exemplary embodiments, four discrete voltages are supplied to the power amplifier. The number of discrete voltages, however, is not limited to four. For example, improved power-added efficiency can be achieved as long as a plurality of discrete voltages include at least the following voltages: a voltage corresponding to the maximum output power; and a voltage corresponding to the output power with the highest frequency of occurrence.

The exemplary aspects of the present disclosure can be used for a wide variety of communication devices, such as mobile phones, as a tracker module that supplies voltage to a power amplifier.

### REFERENCE SIGNS LIST

1 tracker circuit
1A, 1B, 1C, 1D, 1E, 1F, 1G tracker module
2 power amplifier
3 filter
4 antenna
5 RFIC
6 communication device
10 pre-regulator circuit
10A PR switch portion
20 switched-capacitor circuit
20A SC switch portion
30 output switching circuit
30A OS switch portion
40 filter circuit
40A FL switch portion
50 DC power source
60 digital control circuit
60A digital control portion
61 first controller
62 second controller
80, 80C, 80D, 80E, 80F, 81B, 81G, 82B, 82G, 83B, 83G, 84B, 84G, 86B, 86G integrated circuit
90 module laminate
90a, 90b major face
91, 92 resin member
96, 97 conductor wiring line
110, 131, 132, 133, 134, 140 input terminal
111, 112, 113, 114, 130, 141 output terminal
150 external connection terminal
601, 602, 603, 604 control terminal

1. A tracker module comprising:
a module laminate; and
an integrated circuit disposed at the module laminate, the integrated circuit including:
at least one switch included in a converter circuit that is configured to convert an input voltage into a first voltage,
at least one switch included in a switched-capacitor circuit that is configured to generate a plurality of discrete second voltages based on the first voltage,
at least one switch included in an output switching circuit that is configured to selectively output at least one voltage of the plurality of discrete second voltages generated by the switched-capacitor circuit, and
a digital control circuit configured to, based on a digital control signal corresponding to an envelope signal, control the output switching circuit to selectively output the at least one voltage of the plurality of discrete second voltages,
wherein in a plan view of the module laminate, at least one of: (i) the at least one switch included in the output switching circuit and (ii) the digital control circuit, is disposed between the at least one switch included in the converter circuit and the at least one switch included in the switched-capacitor circuit.

2. The tracker module according to claim 1, wherein the at least one switch included in the switched-capacitor circuit is disposed adjacent to the at least one switch included in the output switching circuit.

3. The tracker module according to claim 1, wherein, in the plan view of the module laminate, the at least one switch included in the output switching circuit, and the digital control circuit are disposed between the at least one switch included in the converter circuit and the at least one switch included in the switched-capacitor circuit.

4. The tracker module according to claim 1, wherein, in the plan view of the module laminate, the at least one switch included in the converter circuit, the at least one switch included in the switched-capacitor circuit, and the at least one switch included in the output switching circuit are disposed in a peripheral region within the integrated circuit.

5. The tracker module according to claim 4, wherein, in the plan view of the module laminate, the digital control circuit is disposed more centrally within the integrated circuit than the at least one switch included in the converter circuit, the at least one switch included in the switched-capacitor circuit, and the at least one switch included in the output switching circuit.

6. The tracker module according to claim 1, wherein, in the plan view of the module laminate, the at least one switch included in the switched-capacitor circuit is in a region defined by two elongated regions that extend in mutually intersecting directions, and the two elongated regions are disposed along two peripheral sides of the integrated circuit.

7. The tracker module according to claim 6, wherein the at least one capacitor included in the switched-capacitor circuit is disposed adjacent to the integrated circuit.

8. The tracker module according to claim 4, wherein the at least one switch included in the switched-capacitor circuit is disposed separately in a first region and a second region that are spaced apart from each other.

9. The tracker module according to claim 8, wherein, in the plan view of the module laminate, the digital control circuit is disposed between the first region and the second region.

10. The tracker module according to claim 1, wherein a switch included in the switched-capacitor circuit is connected to a switch included in the converter circuit via an electrically conductive member at the module laminate.

11. The tracker module according to claim 10, wherein the at least one capacitor included in the switched-capacitor circuit is disposed adjacent to the integrated circuit.

12. A tracker module comprising:
a module laminate;
a first integrated circuit disposed at the module laminate and that includes at least one switch in a converter circuit that is configured to convert an input voltage into a first voltage;
a second integrated circuit disposed at the module laminate and that includes at least one switch included in a switched-capacitor circuit that is configured to generate a plurality of discrete second voltages based on the first voltage;
a third integrated circuit disposed at the module laminate and that includes at least one switch included in an output switching circuit that is configured to selectively output at least one voltage of the plurality of discrete second voltages generated by the switched-capacitor circuit; and
a digital control circuit configured to, based on a digital control signal corresponding to an envelope signal, control the output switching circuit to selectively output at least one voltage of the plurality of discrete second voltages, wherein, in a plan view of the module laminate, at least one of: (i) the at least one switch included in the output switching circuit, and (ii) the digital control circuit, is disposed between the at least one switch included in the converter circuit and the at least one switch included in the switched-capacitor circuit.

13. The tracker module according to claim 12, wherein:
the module laminate has a first major face and a second major face that are opposite to each other,
an external connection terminal of the tracker module further is disposed at the second major face, and
the first integrated circuit and the second integrated circuit are disposed at the second major face.

14. The tracker module according to claim 13, wherein:
the third integrated circuit is disposed at the first major face, and the second integrated circuit at least partially overlaps the third integrated circuit in the plan view of the module laminate.

15. A tracker module comprising:
a module laminate; and
a integrated circuit disposed at the module laminate and that includes:
a switched-capacitor circuit that includes a first switch, a second switch, a third switch, a fourth switch, a fifth switch, a sixth switch, a seventh switch, and an eighth switch,
an output switching circuit that includes a ninth switch and a tenth switch that are connected to the switched-capacitor circuit,
a converter circuit that includes an eleventh switch and a twelfth switch that are connected to the switched-capacitor circuit, and
a digital control circuit configured to control the first to twelfth switches, wherein the switched-capacitor circuit includes:
a first capacitor having a first electrode and a second electrode,
a second capacitor having a third electrode and a fourth electrode, and
the first to eighth switches,
wherein a first terminal of the first switch and a first terminal of the third switch are connected to the first electrode,
wherein a first terminal of the second switch and a first terminal of the fourth switch are connected to the second electrode,
wherein a first terminal of the fifth switch and a first terminal of the seventh switch are connected to the third electrode,
wherein a first terminal of the sixth switch and a first terminal of the eighth switch are connected to the fourth electrode,
wherein a second terminal of the first switch, a second terminal of the second switch, a second terminal of the fifth switch, and a second terminal of the sixth switch are connected to each other,
wherein a second terminal of the third switch is connected to a second terminal of the seventh switch,
wherein a second terminal of the fourth switch is connected to a second terminal of the eighth switch,
wherein the output switching circuit includes:
a first output terminal,
the ninth switch connected between the first output terminal, and the second terminal of the first switch, the second terminal of the second switch, the second terminal of the fifth switch, and the second terminal of the sixth switch, and
the tenth switch connected between the first output terminal, and the second terminal of the third switch and the second terminal of the seventh switch,
wherein the converter circuit includes: an input terminal,
the eleventh switch connected between the input terminal and a first end of a power inductor, and
the twelfth switch connected between the first end of the power inductor and ground,
wherein a second end of the power inductor is connected to the second terminal of the first switch, the second terminal of the second switch, the second terminal of the fifth switch, and the second terminal of the sixth switch, and
wherein in a plan view of the module laminate, at least one of: (i) the ninth switch and the tenth switch, and (ii) the digital control circuit, is disposed between: the eleventh switch and the twelfth switch; and the first switch, the second switch, the third switch, the fourth switch, the fifth switch, the sixth switch, the seventh switch, and the eighth switch.

16. The tracker module according to claim 15, wherein the first switch, the second switch, the third switch, the fourth switch, the fifth switch, the sixth switch, the seventh switch, and the eighth switch are each disposed adjacent to the ninth switch and the tenth switch.

17. The tracker module according to claim 15, wherein, in the plan view of the module laminate, the first switch, the second switch, the third switch, the fourth switch, the fifth switch, the sixth switch, the seventh switch, the eighth switch, the ninth switch, the tenth switch, the eleventh switch, and the twelfth switch are disposed in a peripheral region within the integrated circuit.

18. The tracker module according to claim 17, wherein, in the plan view of the module laminate, the digital control circuit is disposed more centrally within the integrated circuit than the first switch, the second switch, the third switch, the fourth switch, the fifth switch, the sixth switch, the seventh switch, the eighth switch, the ninth switch, the tenth switch, the eleventh switch, and the twelfth switch.

19. The tracker module according to claim 15, wherein, in the plan view of the module laminate, the first switch, the second switch, the third switch, the fourth switch, the fifth switch, the sixth switch, the seventh switch, and the eighth switch are disposed in a region defined by two elongated regions extending in mutually intersecting directions, and the two elongated regions are disposed along two peripheral sides of the integrated circuit.

20. The tracker module according to claim 15, wherein at least one of the first switch, the second switch, the third switch, the fourth switch, the fifth switch, the sixth switch, the seventh switch, and the eighth switch, and at least one of the eleventh switch and the twelfth switch are connected to each other via an electrically conductive member provided at the module laminate.
